(19) United States
(12) Patent Application Publication
(10) Pub. No.: US 2026/0365126 A1
(43) Pub. Date: Nov. 19, 2026

(54) RADIO BASED TIME SYNCHRONIZATION OF WIRELESS BATTERY DEVICES

(71) Applicant: Texas Instruments Incorporated, Dallas, TX (US)

(72) Inventors: Minghua Fu, Plano, TX (US); Jyothsna Kunduru, Plano, TX (US); Kwang Seop Eom, Frisco, TX (US); Manoj Raj Madhava Ramakrishna Pillai, Plano, TX (US); Ariton E. Xhafa, Plano, TX (US); Kumaran Vijayasankar, Allen, TX (US); Dag Grini, Skedsmokorset (NO); Evan Ray Wakefield, Allen, TX (US); David Patrick Magee, Allen, TX (US); Brian Paul Burk, Dallas, TX (US); Jan Vencken, Rowlett, TX (US)

(21) Appl. No.: 19/400,806

(22) Filed: Nov. 25, 2025

Related U.S. Application Data
(60) Provisional application No. 63/806,481, filed on May 15, 2025.

(51) Int. Cl. B60R 16/023; B60L 50/60; G01R 31/382; G01R 31/389; G01R 31/392; G01R 31/396; H04J 3/06

(52) U.S. Cl. CPC B60R 16/0231; B60L 50/66; G01R 31/382; G01R 31/389; G01R 31/392; G01R 31/396; H04J 3/0658

(57) ABSTRACT

An example apparatus includes: a wireless receiver configurable to receive a packet, a programmable circuit, and a communication circuit coupled to the wireless receiver and the programmable circuit, wherein the communication circuit is configurable to: identify a portion of the packet; and cause the device to send a first wired signal to a battery monitor circuit in response to identifying the portion of the packet.

### CROSS-REFERENCE TO RELATED APPLICATION

This patent application claims the benefit of and priority to U.S. Provisional Patent Application No. 63/806,481 filed May 15, 2025, which is hereby incorporated herein by reference in its entirety.

### TECHNICAL FIELD

This description relates generally to batteries and, more particularly, to radio-based time synchronization of wireless battery devices.

### BACKGROUND

Hybrid electric vehicles (HEVs) and electric vehicles (EVs) are powered by battery systems that include batteries such as lithium-ion batteries. Battery systems may also include a battery management system to monitor the health of the batteries and report the health to a main electronic control unit (ECU) of the HEVs or EVs. A wide range of conditions may impact the health of the batteries.

### SUMMARY

For radio based time synchronization in wireless battery devices, a first example device includes: a wireless receiver configurable to receive a packet, a programmable circuit, and a communication circuit coupled to the wireless receiver and the programmable circuit, wherein the communication circuit is configurable to: identify a portion of the packet; and cause the device to send a first wired signal to a battery monitor circuit in response to identifying the portion of the packet.

A second example device includes a wireless receiver configurable to receive a packet; a programmable circuit; and a communication circuit coupled to the wireless receiver and the programmable circuit, wherein the communication circuit is configurable to: set a timer in response to the packet; and cause the device to send a first wired signal to a battery monitor circuit at an expiration of the timer.

A third example device includes a wireless transmitter configurable to transmit a downlink packet, a programmable circuit; and a communication circuit coupled to the wireless transmitter and the programmable circuit, wherein the communication circuit is configurable to: after transmission of the downlink packet, set a timer in response to a message from the programmable circuit; cause the device to send a wired signal to a battery monitor circuit at an expiration of the timer.

### BRIEF DESCRIPTION OF THE DRAWINGS

FIG. 1 is an illustrative example of a wireless battery management system (WBMS).

FIG. 2 is a block diagram of a first example implementation of the WBMS of FIG. 1.

FIG. 3 is a block diagram of a second example implementation of the WBMS of FIG. 1.

FIG. 4 is a block diagram of a third example implementation of the WBMS of FIG. 1.

FIG. 5 is a block diagram of a fourth example implementation of the WBMS of FIG. 1.

FIG. 6 is a block diagram of a fifth example implementation of the WBMS of FIG. 1.

FIG. 7 is an illustrative example of a super frame interval usable by the example implementation of the WBMS of FIG. 6.

FIG. 8 is a block diagram of an example implementation of a secondary device of FIG. 6.

FIG. 9 is an illustrative example of timing signals that may be exchanged between devices in the WBMS of FIG. 6.

FIG. 10 is an illustrative example of a just-in-time protocol that may be implemented within the WBMS of FIG. 6.

FIG. 11 is an illustrative example of a schedule protocol that may be implemented within the WBMS of FIG. 6.

FIG. 12 is an illustrative example of backup timers that may be employed within the just-in-time protocol of FIG. 10 or the schedule protocol of FIG. 11.

FIG. 13 is an illustrative example of the performance of the just-in-time protocol of FIG. 10.

FIG. 14 is a second illustrative example of the performance of the schedule protocol of FIG. 11.

FIG. 15 is a flowchart representative of example machine-readable instructions or example operations that may be at least one of executed, instantiated, or performed using an example programmable circuitry implementation of a primary device of FIG. 6.

FIG. 16 is a flowchart representative of example machine-readable instructions or example operations that may be at least one of executed, instantiated, or performed by a secondary device of FIG. 6 to implement the just-in-time protocol.

FIG. 17 is a flowchart representative of example machine-readable instructions or example operations that may be at least one of executed, instantiated, or performed by a secondary device of FIG. 6 to implement the schedule protocol.

FIG. 18 is a flowchart representative of example machine-readable instructions or example operations that may be at least one of executed, instantiated, or performed using an example programmable circuitry implementation of a battery quality (BQ) device of FIG. 6.

FIG. 19 is a block diagram of an example processing platform including programmable circuitry structured to execute, instantiate, or perform the example machine-readable instructions or perform the example operations of FIGS. 15-18 to implement the WBMS 100 of FIG. 6.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Many HEVs and EVs include a system of batteries, wherein each battery includes a plurality (e.g., thousands) of storage cells. Using multiple distributed batteries and/or a large number of distributed cells enables an increased amp-hour capacity than would otherwise be attainable with a single battery or a smaller number of cells. The increased amp-hour capacity improves the functionality of the system (e.g., increased range, torque, or speed of the vehicle, etc.) compared to single battery alternatives and smaller cell alternatives. In some implementations of multiple distributed batteries, one or more individual batteries connect to a controller that coordinates operations at a system-level. In some examples, the individual battery cells or the circuits coupled to the battery cells may be called battery modules, secondary batteries, secondary nodes, secondary network nodes, secondary circuits, monitor circuits, etc. Similarly, the controller may be called a battery controller, a primary node, a primary network node, a primary controller, etc.

In some examples, HVs and EVs combine multiple battery cells to one another in series to create a comparatively high voltage, low current signal that supports efficient electric motor operations. However, battery cells that are coupled to one another in series generally require that a) one primary controller is implemented per battery cell and b) the primary controllers perform operations synchronously with one another. In contrast, battery cells combined to one another in parallel create a comparatively low voltage, high current signal and can generally be controlled by a single primary controller.

Some HVs and EVs enable communication between the battery modules and controller through a series of wired connections. HVs and EVs may also or alternatively use wireless connections to enable communication between the battery modules and the controller. In some examples, implementations utilizing wireless communication may be referred to as wireless battery management systems (WBMSs). In some examples, WBMSs are used instead of wired alternatives because WBMSs reduce weight, complexity, and cost as compared to utilizing wired connections through a vehicle. For example, wired battery systems generally include more components (including but not limited to choke capacitors for isolation/protection between high and low voltage) and require more complexity to repair than WBMSs.

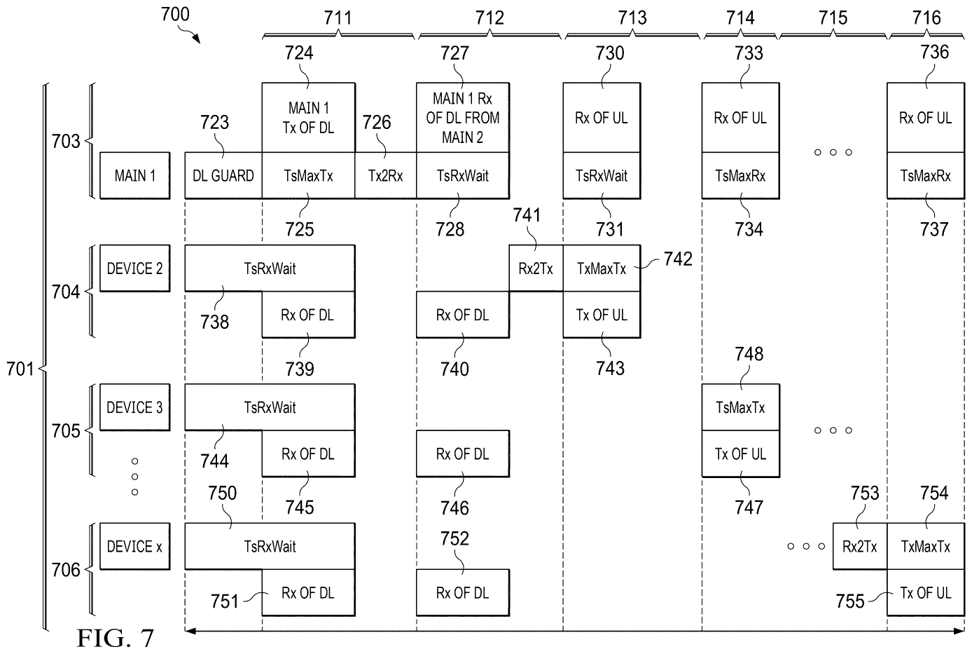

WBMSs may communicate over different protocols based on the use case. For example, in some automotive applications, industry members may use a WBMS superframe to establish communication between multiple battery modules and a controller. As used herein, the term “superframe” refers to a scheduled data exchange window that aggregate several bi-directional transmission slots. As used herein, a superframe may refer to a Transmission System 1 (T1) framing standard or any other bi-directional scheduled transmission protocol. Superframes are described further in connection with at least FIGS. 7A and 7B.

As both the performance requirements and complexity of HV and EV design has increased, the danger of thermal runaway has become increasingly prevalent. Thermal runaway generally refers to an uncontrollable increase of temperature that can lead to fires and/or explosions. Thermal runaway can be caused by a variety of factors that result in a battery cell operating past its thermal limits. Such factors include but are not limited to dendrite growth in batteries, cell battery damage, manufacturing anomalies, etc. New WBMSs are required to meet strict safety requirements to prevent thermal runaway from occurring. If a WBMS determines that thermal runway is no longer preventable, some safety standards require the WBMS to notify the driver a threshold amount of time (e.g., five minutes) before the thermal runaway occurs.

Electrochemical Impedance Spectroscopy (EIS) refers to certain techniques that measure the health of a battery cell. To perform EIS in a manner that supports strict thermal runaway notification standards, devices within the WBMS must be synchronized to one another to an extremely high degree of accuracy that is not supported in WBMSs. In some examples, such a use of EIS techniques requires the clocks within WBMSs is approximately twenty times more accurate than the accuracy of known WBMSs. More generally, the level of synchronization in known WBMSs will tolerate inaccuracies due to system-level latency that occurs when scheduling EIS measurements and subs, but the level of synchronization required to use EIS for strict thermal runaway notification standards cannot support such system-level latency.

Example methods, apparatus, and systems described herein perform EIS measurements with a high degree of accuracy that is agnostic to system-level latency and supports struct thermal runaway notification standards. Example battery management devices within a WBMS include a Radio Frequency (RF) core with a first processor that executes logic independently from a second processor within a system core. In examples described herein, the system core schedules EIS measurements and analyzes the subsequent values to determine the risk of thermal runway, while the RF core synchronizes the WBMS devices to one another and triggers the EIS measurements. WBMS synchronization described herein is therefore more accurate and more robust than known systems.

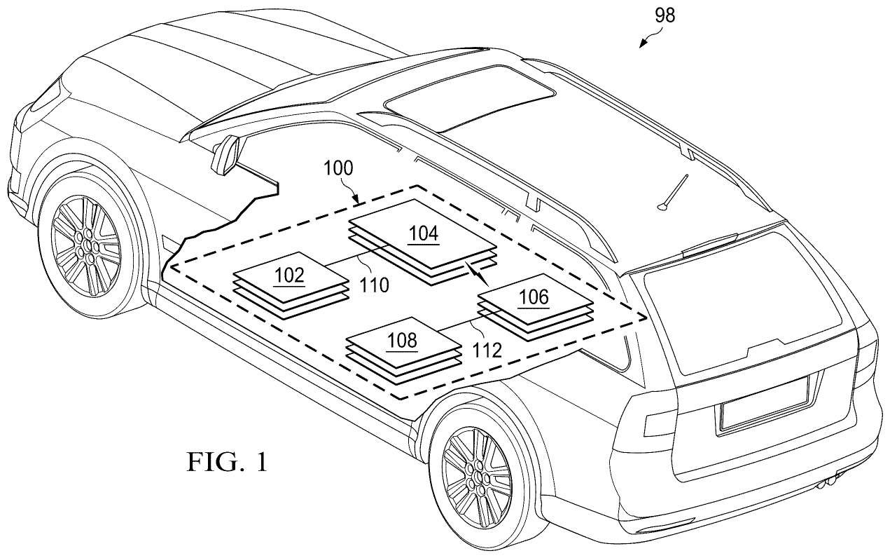

FIG. 1 is a schematic diagram of an automotive system 98 including multiple primary and secondary devices configured to communicate using concurrent superframes. The system 98 may be a vehicle, such as an automobile, a watercraft, an aircraft, a spacecraft, or a military vehicle. The system 98 may also be a non-vehicular system that includes battery cells that are monitored. Further, the system 98 may be any type of system in which information is to be repeatedly communicated between wireless devices. Additional examples of the system 98 may include one or more of the following, in any combination: smartphones; laptop computers; desktop computers; tablets; notebooks; appliances; and entertainment devices. The remainder of this description assumes that the system 98 is an automobile, but the scope of this description is not limited to automobiles or any other particular type of system. Furthermore, although the concurrent superframe scheme is described herein within the context of wireless battery management systems, the teachings of this description may be extended to other types of systems, including smart home, home automation, industrial automation (e.g., finely tuned machines), robotics, security and surveillance, internet of things, and wireless sensor networks.

The example system 98 includes a wireless battery management system (WBMS) 100. The WBMS 100 may be positioned in any part of the automobile, but in some examples, the WBMS 100 is positioned in, on, or near a bottom part of a chassis of the automobile, such as below one or more seats of the automobile. The WBMS 100 may include one or more battery controller devices 102 that oversees and controls the WBMS 100 (e.g., by load balancing among devices and determining whether to measure current, voltage, temperature, or other register settings of battery cells); one or more primary devices 104 coupled to the battery controller devices 102 by way of one or more wired or wireless connections 110; one or more secondary devices 106; and one or more battery cells 108 coupled to the one or more secondary devices 106 by way of one or more wired or wireless connections 112. The primary devices 104 communicate wirelessly with the secondary devices 106 using a concurrent superframe protocol, as described herein.

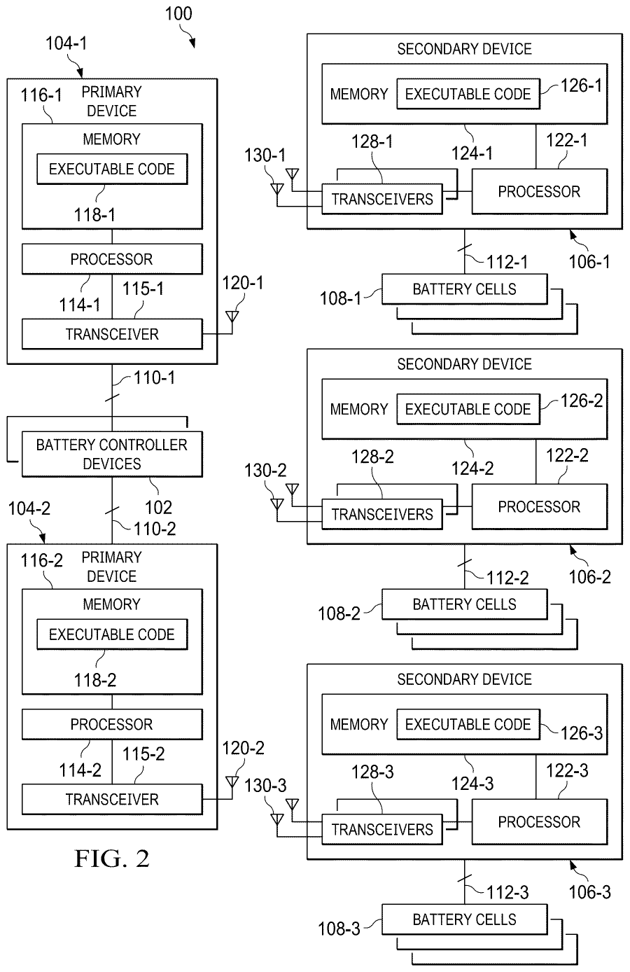

FIG. 2 is a block diagram of the WBMS 100 of FIG. 1. The WBMS 100 may include one or more battery controller devices 102 that are coupled to primary devices 104-1 and 104-2 by way of one or more wired or wireless connections 110-1 and 110-2, respectively. The primary device 104-1 includes processor circuitry 114-1, a transceiver 115-1 coupled to the processor circuitry 114-1, and memory 116-1 (e.g., random access memory (RAM), and read-only memory (ROM)) coupled to the processor circuitry 114-1. The memory 116-1 stores executable code 118-1. The processor circuitry 114-1, upon executing the executable code 118-1, performs some or all of the actions attributed herein to the primary device 104-1 or to the processor circuitry 114-1. An antenna 120-1 is coupled to the transceiver 115-1 and is configured to transmit signals to and receive signals from other devices in the WBMS 100. The primary device 104-2 includes processor circuitry 114-2 coupled to a transceiver 115-2 and memory 116-2 (e.g., RAM or ROM). The memory 116-2 stores executable code 118-2. The processor circuitry 114-2, upon executing the executable code 118-2, performs some or all of the actions attributed herein to the primary device 104-2 or the processor circuitry 114-2. An antenna 120-2 is coupled to the transceiver 115-2 and is configured to transmit signals to and receive signals from other devices in the WBMS 100. In some examples, a primary device (e.g., 104-1) is referred to as a primary wireless device.

Any processors described herein may be implemented by any type of programmable circuitry. Examples of programmable circuitry include but are not limited to programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs).

Further, any transceivers described herein may use the license-free 2.4 gigahertz (GHz) industrial, scientific, and medical (ISM) band from 2.4 GHz to 2.483 GHz, which is compliant with the Bluetooth Special Interest Group (SIG). Also or alternatively, the transceivers may use 2 megabits per second (Mbps) Bluetooth Low Energy (BLE) across the physical layer (PHY). The Open Systems Interconnection (OSI) model includes the PHY as a layer used for communicating raw bits over a physical medium. In examples described herein, the PHY is free space, which the WBMS 100 uses to wirelessly communicate between the various devices of the WBMS 100. In some examples, the transceivers described herein are instantiated by programmable circuitry executing RF instructions.

A secondary device 106-1 may include a processor 122-1 coupled to a memory 124-1 storing executable code 126-1. The processor 122-1, upon executing the executable code 126-1, may perform some or all of the actions attributed herein to the secondary device 106-1 or the processor 122-1. One or more transceivers 128-1 are coupled to the processor 122-1, and one or more antennas 130-1 are coupled to the one or more transceivers 128-1. The secondary device 106-1 is coupled to one or more battery cells 108-1 by way of one or more connections 112-1.

A secondary device 106-2 may include a processor 122-2 coupled to a memory 124-2 storing executable code 126-2. The processor 122-2, upon executing the executable code 126-2, may perform some or all of the actions attributed herein to the secondary device 106-2 or the processor 122-2. One or more transceivers 128-2 are coupled to the processor 122-2, and one or more antennas 130-2 are coupled to the one or more transceivers 128-2. The secondary device 106-2 is coupled to one or more battery cells 108-2 by way of one or more connections 112-2.

A secondary device 106-3 may include a processor 122-3 coupled to a memory 124-3 storing executable code 126-3. The processor 122-3, upon executing the executable code 126-3, may perform some or all of the actions attributed herein to the secondary device 106-3 or the processor 122-3. One or more transceivers 128-3 are coupled to the processor 122-3, and one or more antennas 130-3 are coupled to the one or more transceivers 128-3. The secondary device 106-3 is coupled to one or more battery cells 108-3 by way of one or more connections 112-3.

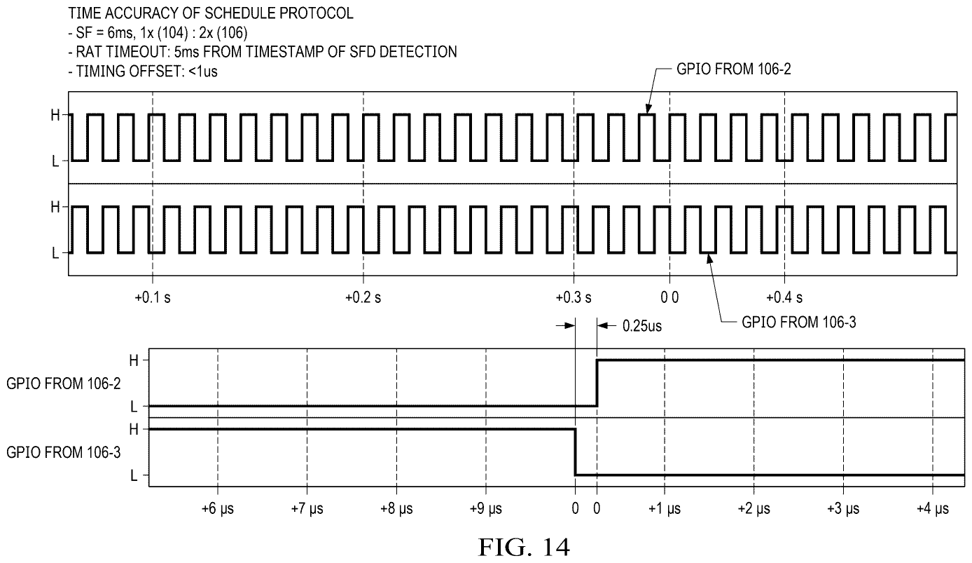

The primary devices 104-1, 104-2 of FIG. 2 may be collectively referred to herein as primary devices 104. Similarly, the secondary devices 106-1, 106-2, 106-3 may be collectively referred to herein as secondary devices 106, and so on. A similar convention may be used for any or all of the features depicted in the drawings. In some examples, one or more of the primary devices 104 are instantiated by programmable circuitry executing primary instructions to perform operations such as those represented by the flowchart(s) of FIGS. 14-20. In some examples, one or more of the secondary devices 106 are instantiated by programmable circuitry executing secondary instructions to perform operations such as those represented by the flowchart(s) of FIG. 14-20.

The primary and secondary devices described herein (e.g., primary devices 104, secondary devices 106) may be implemented as a CC2662 or a BQ79616 made by TEXAS INSTRUMENTS INC.® of Dallas, TX. Additional example details of the CC2662 and BW79616 can be found in the datasheet entitled “CC2662R-Q1 SimpleLink™ Wireless BMS MCU,” revised July 2023, available at https://www.ti.com/product/CC2662R-Q1, and the datasheet entitled “BQ79616-Q1, BQ79614-Q1, BQ79612-Q1 Functional Safety-Compliant Automotive 16S/14S/12S Battery Monitor, Balancer and Integrated Hardware Protector,” revised September 2022, available at https://www.ti.com/product/BQ79616-Q1, each of which is incorporated by reference in its entirety. As just one example, a secondary device 106 may be implemented as CC2662 for communication coupled to a BQ79616 for battery monitoring. Additional examples of WBMS architecture and communication can be found in commonly assigned U.S. Application Publication No. 2025/0008491, entitled “Hierarchical Wireless Battery Management System” filed Jun. 30, 2023, commonly assigned U.S. application Ser. No. 18/647,353, entitled “Scheduling for Multiple Primary Nodes,” filed Apr. 26, 2024, commonly assigned U.S. Application Publication No. Ser. No. 19/213,653, entitled “Time Synchronization In Wireless Battery Management Systems” filed May 20, 2025, and commonly assigned U.S. application Ser. No. 19/213,668, entitled “Time Synchronization In Wireless Battery Management Systems” filed May 20, 2025, each of which is hereby incorporated herein by reference in its entirety.

The secondary devices 106 are configured to monitor the status of respective battery cells 108 (e.g., the voltage being provided by the battery cells 108, the temperatures of battery cells 108). For example, a given secondary device 106-1 may include, or be coupled to, or communicate, with one or more sensors configured to measure a variety of parameters associated with the corresponding battery cells 108-1. The sensors may relay the sensed data to the processors 122 of the secondary devices 106 by way of a universal asynchronous receiver/transmitter (UART) protocol or any other suitable protocol. Further, a given secondary device 106-1 may be configured to communicate with one or both of the primary devices 104. For example, the secondary device 106-1 may communicate with the primary device 104-1 during one slot of a superframe, and the secondary device 106-1 may communicate with the primary device 104-2 during a different slot of the superframe. Alternatively, the secondary device 106-1 may communicate with both primary devices 104 simultaneously using different transceivers 128-1. The secondary devices 106-2 and 1006-3 may communicate with both primary devices 104 similarly to the secondary device 106-1. In some examples, a given secondary device 106-1 is configured to communicate with one or more of the remaining secondary devices 106-2, 106-3. The primary devices 104 also may communicate with the secondary devices 106 and with one other. For example, the primary device 104-1 may transmit data to one or more of the primary device 104-2, the secondary device 106-1, the secondary device 106-2, or the secondary device 106-3. The primary device 104-2 may operate similarly as the primary device 104-1. The communications that are transmitted by the primary devices 104 may be received from one or more of the battery controller devices 102. Similarly, the communications that are received by the primary devices 104 may be provided to one or more of the battery controller devices 102.

The WBMS 100 as depicted in FIG. 2 is illustrative. In some examples, the WBMS 100 may include any number of primary devices, secondary devices, battery controllers, battery cells, other components, and wired or wireless connections between one or more of the foregoing. Any and all such variations are contemplated and included in the scope of this description.

Additional examples of the components shown in FIGS. 1 and 2 can be found in commonly assigned U.S. Application Publication No. 2024/0069110, entitled “Multiple Primary Nodes for Wireless Battery Management System Robustness,” filed Aug. 30, 2022, and is hereby incorporated herein by reference in its entirety.

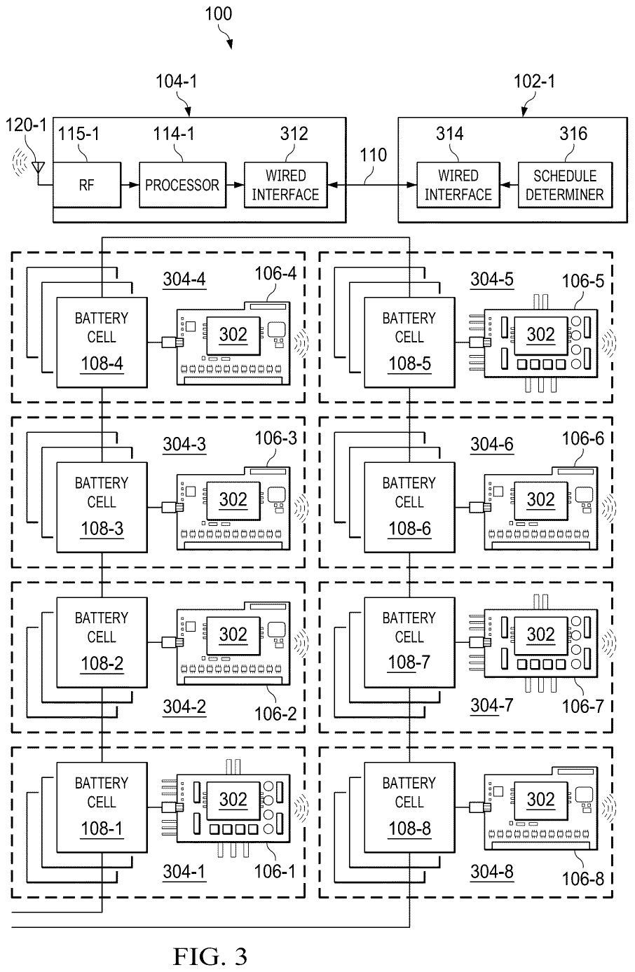

FIG. 3 is a block diagram of an implementation of the WBMS 100 of FIG. 1. The WBMS 100 of FIG. 3 is configured to operate based on the concurrent superframe scheme as described further in FIGS. 7A and 7B. The WBMS 100 of FIG. 3 may be instantiated (e.g., creating an instance of, bring into being for any length of time, materialize, implement, etc.) by programmable circuitry such as a CPU executing first instructions. Also or alternatively, the WBMS 100 of FIG. 3 may be instantiated by (i) an ASIC or (ii) a FPGA structured or configured in response to execution of second instructions to perform operations corresponding to the first instructions. Some or all of the circuitry of FIG. 3 may, thus, be instantiated at the same or different times. Some or all of the circuitry of FIG. 3 may be instantiated, for example, in one or more threads executing concurrently on hardware or in series on hardware. Moreover, in some examples, some or all of the circuitry of FIG. 3 may be implemented by microprocessor circuitry executing instructions or FPGA circuitry performing operations to implement one or more virtual machines or containers.

The example block diagram of FIG. 3 includes the battery controller device 102-1, the primary device 104-1, secondary devices 106-1 through 106-8, and battery cells 108-1 through 108-8. The primary device 104-1 includes the antenna 120-1, radio frequency (RF) transceiver 115-1, the processor circuitry 114-1 of FIG. 1, and example wired interface circuitry 312. The battery controller device 102-1 includes example wired interface circuitry 314 and example schedule determiner circuitry 316.

In the example of FIG. 3, the respective secondary devices 106 include schedule requester circuitry 302. As used herein, a secondary device 106-1 and its corresponding battery cell(s) 108-1 may be collectively referred to as a battery module 304-1. Accordingly, the battery modules 304-1 through 304-8 collectively form battery modules 304.

The scope of this description is not limited to any particular number of each type of device illustrated in FIG. 3. Accordingly, the WBMS 100 of FIG. 3 may include any number of battery controller devices 102, primary devices 104, or battery modules 304. In some examples, the WBMS 100 includes two or more battery controller devices 102, where a first set of the secondary devices 106 are assigned to communicate with a first battery controller device 102-1, and a second set of the secondary devices 106 are assigned to communicate with a second battery controller device 102-2. The first and second sets of secondary devices may or may not overlap.

Within the primary device 104-1, the wired interface circuitry 312 sends and receives communications with the battery controller device 102-1 via the wired connection 110. The wired interface circuitry 312 may implement any suitable hardware components, including but not limited to terminals, pins, interconnects, etc., to implement wired communications. Similarly, within the battery controller device 102-1, the wired interface circuitry 314 sends and receives communications with the primary device 104 via the wired connection 110. The wired interface circuitry 314 may implement any suitable hardware components to implement wired communications. In examples, the wired interface circuitry 312, 314 may be replaced by transceivers or other circuitry suitable to facilitate wireless communications between the primary device 104 and the battery controller device 102-1.

The schedule determiner circuitry 316 determines different communication schedules for different superframes. The schedule determiner circuitry 316 adjusts a schedule or creates new schedules for superframes based on the transmission request transmitted by the multiple instances of the schedule requester circuitry 302. In the example of FIG. 3, the schedule determiner circuitry 316 is implemented within the battery controller device 102-1. In other examples, the schedule determiner circuitry 316 is implemented within the primary device 104 or elsewhere within the WBMS 100. In some examples, the schedule determiner circuitry 316 is instantiated by programmable circuitry executing schedule determiner instructions.

The battery modules 304 wirelessly communicate with the primary device 104-1 using concurrent superframes. Accordingly, a first superframe containing a first set of communications occurs at the same time as a second superframe containing a second set of communications. Within a given battery module 304-1, the schedule requester circuitry 302 determines whether a transmission regarding the corresponding battery cell 108-1 is made in an upcoming set of concurrent superframes. The schedule requester circuitry 302 may determine when to schedule a given transmission based on factors that include status and performance of the corresponding battery cell 108-1.

The schedule requester circuitry 302 optionally requests to be included on a schedule for an upcoming superframe based on the result of the determination. Accordingly, the battery modules 304 do not request a transmission in an upcoming superframe every time an opportunity to request is available. The schedule requester circuitry 302 may provide additional information to the battery controller device 102-1 when requesting a transmission in an upcoming superframe. The schedule requester circuitry 302 may also request a specific number of requested time slots, request a specific duration of uplink time, or request a specific data size to uplink (e.g., a specific number of blocks, bytes, or bits), etc. Alternatively, the request sent by the schedule requester circuitry 302 may indicate only that a corresponding battery module 304-1 is requesting more time for transmission, without any specifics about the requested time duration, number of time slots, or uplink size.

In the example of FIG. 3, each instance of the schedule requester circuitry 302 is implemented within the secondary devices 106. In other examples, one or more instances of the schedule requester circuitry 302 are implemented elsewhere within the respective battery modules 304. In some examples, the schedule requester circuitry 302 is instantiated by programmable circuitry executing schedule requester instructions.

The battery modules 304 are heterogeneous in the sense that the design, manufacture, capabilities, or performance of a first battery module may differ from that of a second battery module. For example, in FIG. 3, battery cells 108-1, 108-2, 108-4 store a larger amount of charge than battery cells 108-3, 108-5-108-8. Furthermore, the amount of charge stored in battery cells 108-1, 108-2, 108-4 is nonuniform. In an additional example, FIG. 3 illustrates the secondary devices 106-1, 106-5, 106-7 implemented by a first type of programmable circuitry, and secondary devices 106-2-106-4, 106-6, 106-8 implemented by a different type of programmable circuitry. While the example FIG. 3 illustrates variance in battery capacity and type of programmable circuitry, in practice, the battery modules 304 may include other types of differences.

In some examples, the heterogeneity of the WBMS 100 causes some battery modules to seek communication with the battery controller device 102-1 more frequently than other battery modules. Some battery modules may also or alternatively transmit different types of information within a superframe than other battery modules. For example, the battery module 304-1 may seek to report a storage capacity measurement when the battery module 304-2 seeks to report an error code. The battery controller device 102-1 enables such diverse forms of communication by receiving requests for transmissions sent by the battery modules 304 and determining a schedule for each superframe. Such techniques are described in commonly assigned U.S. Application Publication No. 2025/0039859, entitled “Methods and Apparatus to Determine Communication Schedules for Wireless Battery Systems,” filed Jul. 28, 2023, which is hereby incorporated herein by reference in its entirety.

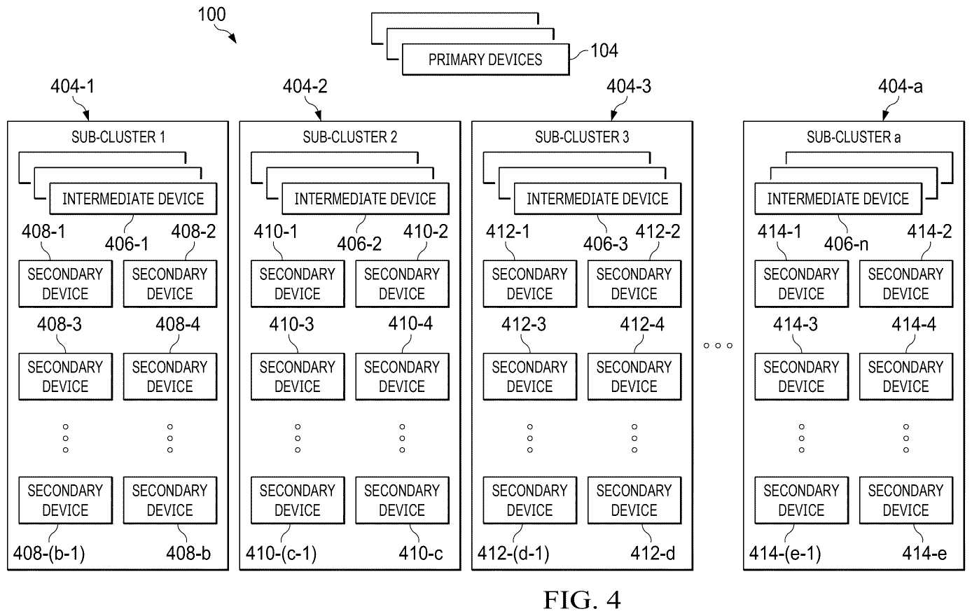

FIG. 4 is a block diagram of another implementation of the WBMS 100 of FIG. 1. The architecture of the WBMS 100 in the example of FIG. 4 includes a layer of intermediate devices between the primary and secondary devices, thus facilitating scale in especially large or complex systems. The example of FIG. 4 includes one or more primary devices 104 and multiple sub-clusters 404-1 through 404-n (collectively referred to herein as sub-clusters 404).

The sub-cluster 404-1 includes one or more intermediate devices 406-1 and multiple secondary devices 408-1 through 408-b (collectively referred to herein as secondary devices 408). The sub-cluster 404-2 includes one or more intermediate devices 406-2 and multiple secondary devices 410-1 through 410-c (collectively referred to herein as secondary devices 410). The sub-cluster 404-3 includes one or more intermediate devices 406-3 and multiple secondary devices 412-1 through 412-d (collectively referred to herein as secondary devices 412). The sub-cluster 404-a includes one or more intermediate devices 406-n and multiple secondary devices 414-1 through 414-e (collectively referred to herein as secondary devices 414). While the letters a, b, c, d, and e are used in FIG. 4 to indicate a plurality of reference numerals, the size of a given plurality need not be equal to the size of any other plurality. For example, in FIG. 4, the number of secondary devices 408 may be the same or different than the number of secondary devices 410, 412, or 414, the number of sub-clusters 404 may be the same or different than the number of secondary devices 408, 410, 412, or 414, etc.

In operation, the secondary devices shown in FIG. 4 collects data, such as the battery cell status data described above, and provides the data to a corresponding intermediate device 406. For example, each of the secondary devices 408 collects data and transmits the data to first and second intermediate devices 406-1. These transmissions occur according to the concurrent superframe scheme described herein, such as with reference to FIGS. 7A and 7B. Thus, for instance, the first and second intermediate devices 406-1 may broadcast downlink synchronization information during first and second slots of concurrent superframes. The secondary devices 408 may receive the broadcast information and use the broadcast information to synchronize communications with the first and second intermediate devices 406-1. Thereafter, during the concurrent superframes, each of the secondary devices 408 may transmit its respective data twice, once in one slot to the first intermediate device 406-1, and again in another slot to the second intermediate device 406-1, with both transmissions occurring on different frequencies. In this way, the first and second intermediate devices 406-1 are substantially likely to receive at least one instance of the data from each of the secondary devices 408. Each of the sub-clusters 404 operates in a similar manner.

After the intermediate devices 406 of each sub-cluster 404 has received the data from respective secondary devices, the intermediate devices 406 transmit the data to the primary devices 104 using the concurrent superframe scheme described herein. For example, in first and second slots of concurrent superframes, first and second primary devices 104 may broadcast downlink synchronization information to the intermediate devices 406, which the intermediate devices 406 may use to synchronize communications with the first and second primary devices 104. Thereafter, during the concurrent superframes, each of the intermediate devices 406 may transmit respective data twice, once in one slot to the first primary device 104, and again in another slot to the second primary device 104, with both transmissions possibly occurring on different frequencies. In this way, the first and second primary devices 104 are substantially likely to receive at least one instance of the data from each of the intermediate devices 406. The concurrent superframe scheme described herein may be scaled to any number of wireless devices in a WBMS, or any other system besides a WBMS in which robust wireless communications are useful. For example, three or more primary devices 104 may be used, in which case a given intermediate device 406 may transmit the same data to the three or more primary devices 104 during different slots and on different frequencies. In some examples in which three or more primary devices 104 may be used, a first intermediate device 406 may transmit data to first and second primary devices 104 in different slots and on different frequencies, while a second intermediate device 406 transmits different data to second and third primary devices 104 in different slots and on different frequencies. Furthermore, the concepts described herein may be extended to any number of concurrent superframes.

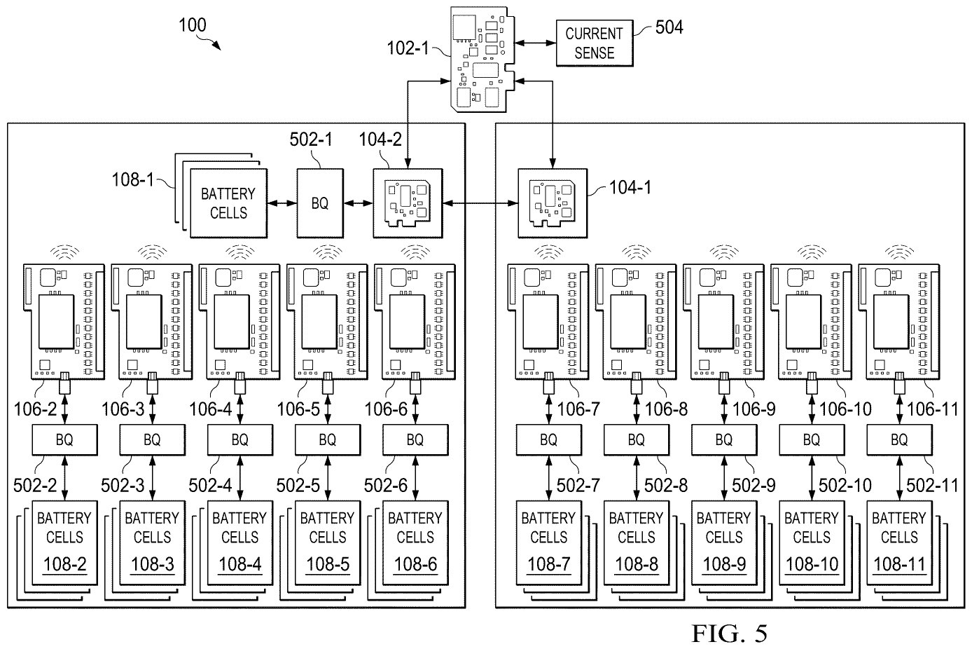

FIG. 5 is a block diagram of an implementation of the WBMS 100 of FIG. 1. The example of FIG. 5 includes one battery controller device 102-1, two primary devices 104, eleven secondary devices 106, and eleven battery cells 108 as described above in one or more of FIGS. 1-4 . FIG. 5 also includes example BQ circuits 502-1 through 502-11 (collectively referred to as BQ circuits 502) and a current sense device 504. The scope of this description is not limited to any particular number of each type of device illustrated in the example of FIG. 5.

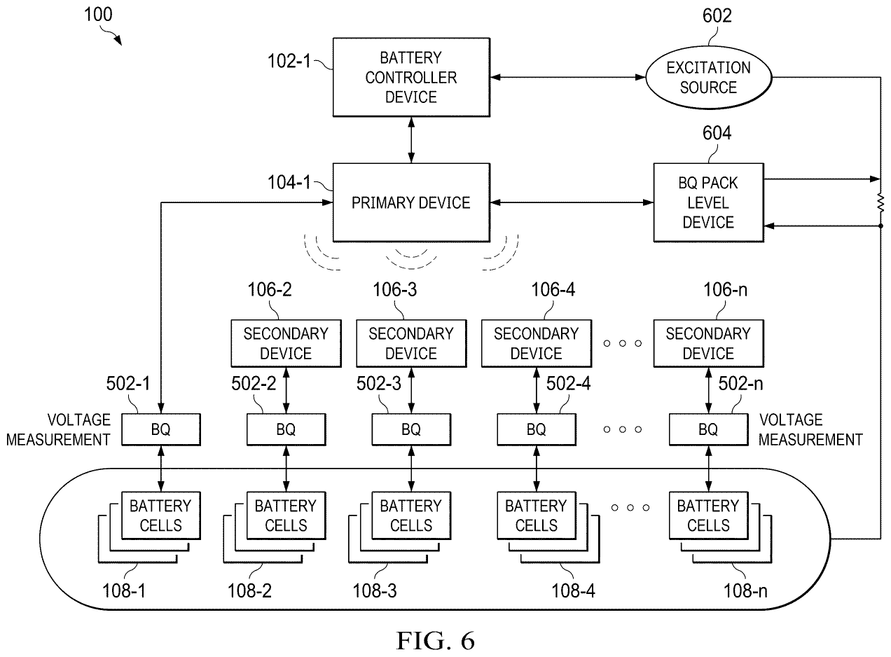

A given BQ circuit 502-1 is configured to monitor the quality, status, and health of its respective battery cells 108-1. For example, Electrochemical Impedance Spectroscopy (EIS) refers to certain techniques that measure the health of a battery cell. Within the set of operations performed across the WBMS 100 to implement EIS, a given BQ circuit 502-1 measures the voltages across the corresponding battery cells 108-1. As part of the EIS technique, the WBMS 100 aims to perform battery measurements synchronously. For example, the BQ circuit 502-1 preferably measures voltage across all of the battery cells 108-1 at the same time that the BQ circuit 502-2 measures voltages across all of the battery cells 108-2. In some examples, the current sense device 504 also measures current flow across the battery cells 108 as part of the EIS techniques. Such current sensing operations are described further in connection with at least FIG. 6. In some examples, a given BQ circuit is referred to as a BQ chip.

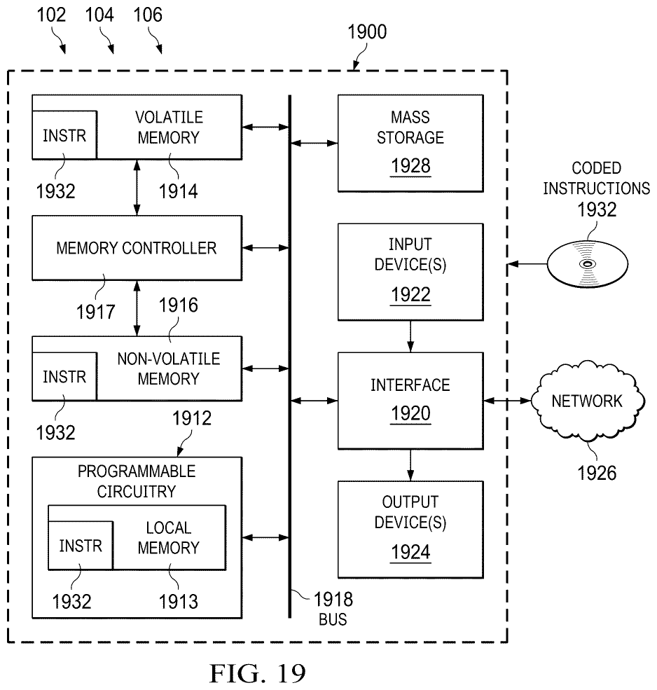

The BQ circuits 502 may perform additional operations to monitor the quality, status, or health of the battery cells. Such additional operations include but are not limited to temperature measurements. In some examples, the BQ circuits 502 are referred to as module-level circuits because there is one BQ circuit 502-1 per module 304-1 (or per group of battery cells 108-1) as described in FIG. 3. In some examples, a given BQ circuit 502-1 is referred to as a monitor circuit or as a Battery Monitor Integrated Circuit (BMIC). As used above and herein, the terms “quality,” “status,” and “health” may be used interchangeably when referring to the monitoring operations performed by the BQ circuits 502. The BQ circuits 502 may be implemented by any type of programmable circuitry. In some examples, the BQ circuits 502 are instantiated by programmable circuitry executing module-level BQ instructions to perform operations such as those represented by the flowchart(s) of FIG. 19.

The BQ circuits 502 may be implemented in a wide variety of architectures. In the example of FIG. 3, the functionality of the BQ circuits 502 is implemented within the secondary devices 106 as described above. In the example of FIG. 5, the BQ circuits 502 are implemented as a separate, standalone device. The BQ circuits 502-2 through 502-11 communicate with their respective primary devices 104 using the secondary devices 106-2 through 106-11, which act as intermediate devices. Accordingly, the BQ circuits 502-2 through 502-11 are wirelessly connected to the primary devices 104. However, the BQ circuit 502-1 is directly coupled (without an intermediate device) to the primary device 104-2 over a wired connection. Thus, the example of FIG. 5 shows a hybrid battery system that includes communication over both wireless and wired connections. Known WBMSs do not support EIS techniques in such a hybrid battery system because the difference in communication latency between the wired and wireless transmission mediums conflict with the goal of all BQ circuits 502 recording voltage measurements at the same time. Advantageously, the techniques described in the examples herein overcome these conflicts to support EIS operations within hybrid battery systems.

The example of FIG. 5 also shows an environment where, like FIG. 4, the large number of secondary devices 106 and battery cells 108 drives a need for multiple primary devices 104-1 and 104-2. In this example, the secondary devices 106-7 through 106-11 communicate wirelessly with the primary device 104-1 while the secondary devices 106-2 through 106-6 communicate wirelessly with the primary device 104-2.

In general, WBMS protocols have strict performance requirements that are difficult to meet with more than one primary device. For example, some WBMS protocols include a bandwidth of approximately 600 kbps or greater, data latency of approximately 100 milliseconds or less, a packet error rate of approximately 10-5 or less, and power consumptions of less than approximately 1 milliampere (mA) at the primary devices 104 and less than approximately 300 microamperes (μA) at the secondary devices 106. In some examples, the primary devices 104-1 and 104-2 run with independent clocks, which can cause a super frame interval of the primary device 104-2 to be behind or ahead in time relative to a super frame interval of the primary device 104-1.

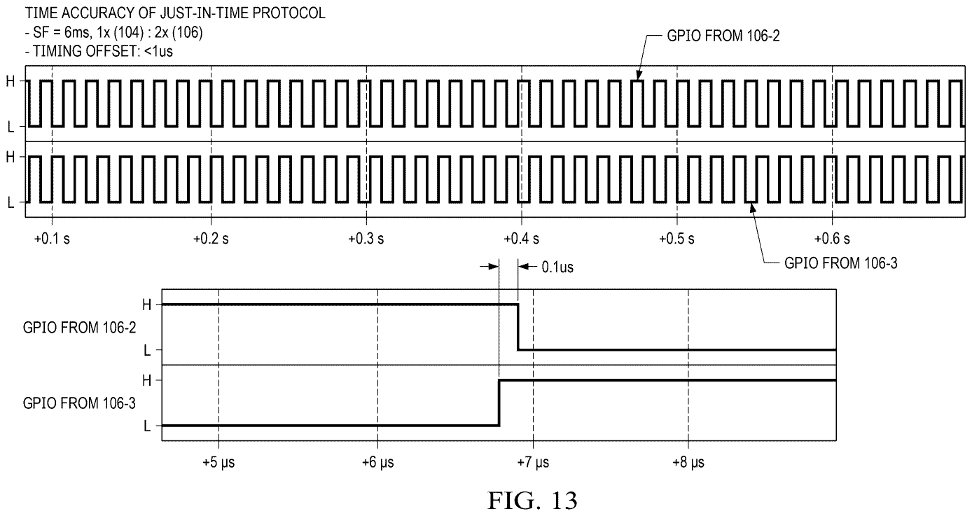

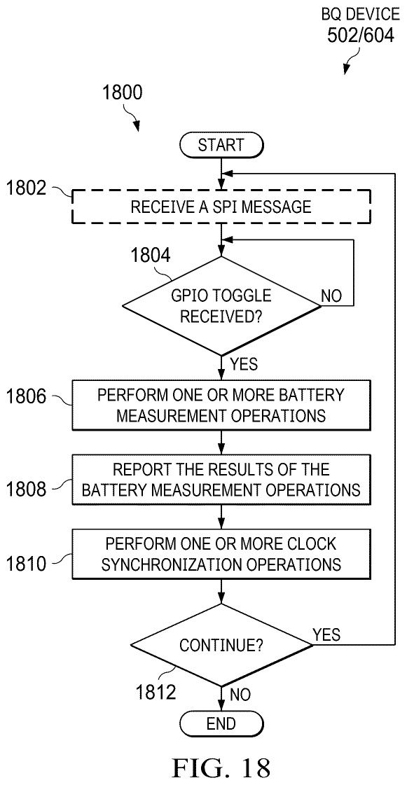

In the intra-network interference perspective, three challenges are addressed. First, the primary devices 104 within a given implementation of the WBMS 100 (e.g., 104-1 and 104-2 in FIG. 5) are preferably synchronized in time. Second, the concurrent superframes of the primary devices 104 preferably do not overlap in frequency. Third, the primary devices 104 are preferably able to start operation at the same time based on the command from a host device. The techniques of this description may address at least the first and second challenges. Such techniques are described further in at least FIGS. 13 and 18.

FIG. 6 is a block diagram of an implementation of the WBMS 100 of FIG. 1. The WBMS of FIG. 6 may be instantiated (e.g., creating an instance of, bring into being for any length of time, materialize, implement, etc.) by programmable circuitry such as a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Also or alternatively, the WBMS of FIG. 6 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the circuitry of FIG. 6 may, thus, be instantiated at the same or different times. Some or all of the circuitry of FIG. 6 may be instantiated, for example, in one or more threads executing concurrently on hardware or in series on hardware. Moreover, in some examples, some or all of the circuitry of FIG. 6 may be implemented by microprocessor circuitry executing instructions or FPGA circuitry performing operations to implement one or more virtual machines or containers.

The example of FIG. 6 includes one battery controller device 102-1, two primary devices 104, (n-1) secondary devices 106, n battery cells 108, and n BQ circuits 502 as described above in one or more of FIGS. 1-5 . FIG. 5 also includes an example excitation source 602 and a BQ pack-level device 604. The scope of this description is not limited to any particular number of each type of device illustrated in the example of FIG. 5.

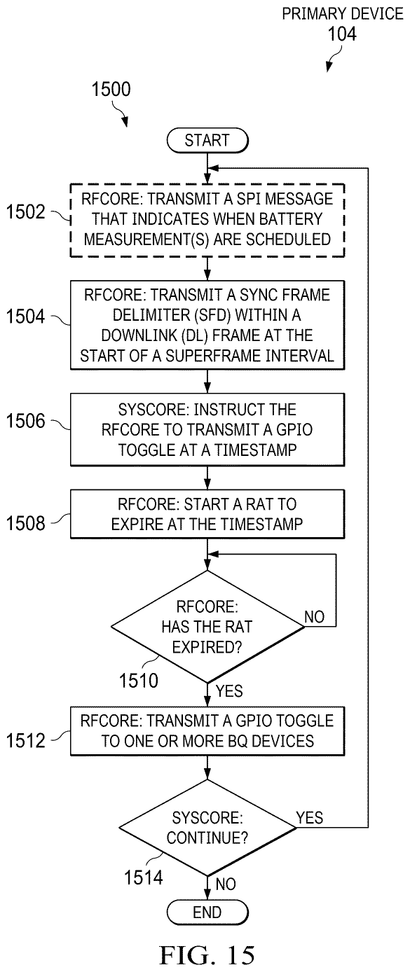

Like FIG. 5, the example of FIG. 6 shows a hybrid battery system that supports EIS operations. In the example of FIG. 6, the battery controller device 102-1 manages the EIS measurements and performs the subsequent analysis of the EIS measurements. More generally, the battery controller 102-1 is responsible for monitoring and regulating the health of the WBMS 100. Thus, as described further below, the battery controller device 102-1 includes logic to at least: synchronize the measurements of the BQ circuits 502 to one another in time, synchronize measurements from the BQ pack-level device 604 in time with measurements from the BQ circuits 502, determine when the EIS measurements occur, and monitor battery health using the synchronized current and voltage measurements. In other examples, one or more portions of the foregoing logic are distributed across any number of devices containing programmable circuitry (e.g., including but not limited to the primary devices 104). For example, the WBMS 100 may be implemented without a battery controller device 102-1 where the primary device 104-1 is configurable to perform the operations ascribed to battery controller device 102-1 herein. In some examples, the primary devices 104 and secondary devices 106 are instantiated by programmable circuitry executing wireless device instructions to perform operations such as those represented by the flowchart(s) of FIGS. 15-17 .

In general, EIS refers to techniques that analyze how a battery responds to an AC signal. The excitation source 602 generates this AC signal based on instructions from the battery controller device 102. In some examples, the AC signal may correspond to multiple pulses over a range of frequencies. Devices within the WBMS 100 then measure the impedance of the battery cells 108 based on their response to the AC signal. In the example of FIG. 6, impedance is measured using both module-level voltage measurements from the BQ circuits 502 and from pack-level current measurements from the BQ pack-level device 604. As used above and herein, a “pack” refers to all battery cells 108 within a given WBMS 100

The BQ pack-level device 604 is an example implementation of the current sense device 504 of FIG. 5. Accordingly, the BQ pack-level device 604 measures the current flowing through the pack of battery cells 108 as described above. In some examples, the BQ pack-level device 604 is referred to as a monitor circuit or as a Pack Monitor Integrated Circuit (PMIC). The BQ pack-level device 604 may be implemented by any type of programmable circuitry. In some examples, the BQ pack-level device 604 is instantiated by programmable circuitry executing BQ pack-level instructions to perform operations such as those represented by the flowchart(s) of FIG. 18.

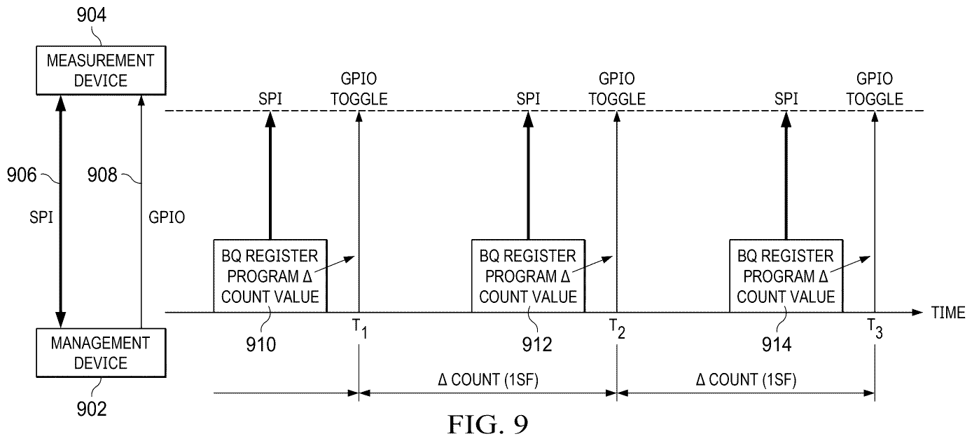

In this example, the BQ pack-level device 604 is coupled to the primary device 104-1 over a wired connection. Thus, the example of FIG. 6 shows a hybrid battery system in the sense that some monitor circuits (502-1 and 604) communicate with the battery controller device 102-1 exclusively over wired mediums while other monitor circuits (502-2 through 502-n) communicate with the battery controller device 102-1 over a wireless medium. In other examples, the BQ pack-level device 604 is coupled to the battery controller device 102-1 over a wireless medium. Moreover, in the example of FIG. 6, the primary device 104-1 utilizes the wired connection to ensure the BQ pack-level device 604 is synchronized to the rest of the WBMS 100. The primary device 104-1 does so by sending a reference signal and messages to the BQ pack-level device 604 over the wired connection as described further in connection with at least FIG. 9.

In other examples, the BQ pack-level device 604 is directly coupled (without an intermediate device) to the battery controller device 102-1 over a wired connection. In such examples, the primary device 104-1 still sends a reference signal and messages to the BQ pack-level device 604, but the transmissions are routed through the battery controller device 102-1. In still other examples, the WBMS 100 does not include the excitation source 602 or the BQ pack-level device 604.

Like FIG. 5, the example of FIG. 6 also shows an implementation of the WBMS 100 that includes two primary devices 104. In this example, the primary device 104-1 communicates to the BQ circuit 502-1 through a wired medium and communicates wirelessly with the secondary devices 106-2 through 106-n. An example superframe interval for primary device 104-1 is described further in connection with FIG. 7.

FIG. 7 depicts a timing diagram 700 illustrating a concurrent superframe communication protocol which may be implemented by the WBMS 100 in one or more of the example implementations of FIGS. 1-6 . Specifically, the timing diagram 700 includes a superframe 701 that includes multiple slots during which various devices in the WBMS 100 may transmit or receive data using Time Division Multiple Access (TDMA) techniques. For example, the superframe 701 includes slots 711-716.

Superframe 701 describes the behavior of devices 703-706. In the example shown, device 703 may be the primary device 104-1 as shown in FIG. 6. The remaining devices 704-706 may be the secondary devices 106-2 through 106-x as described above in reference to FIG. 6. For ease of description, FIG. 7 labels devices 703-706 as “main 1,” “device 2,” “device 3,” and “device x,” respectively.

In other examples, the devices 703-706 of FIG. 7 refer to a different combination of primary devices 104 and secondary devices 106. In some such examples, a given secondary device may communicate with multiple primary devices 104 on concurrent superframe intervals or switch from a first primary device 104-1 to a second primary device 104-2 between consecutive superframe intervals. Such a secondary device may communicate with multiple primary devices 104 over multiple time slots to mitigate the risk of data loss through data retransmission.

Prior to the first slot 711, the superframe 701 enables Down Link (DL) guard transmission periods 723, which is useful to mitigate the risk of interference with other superframes that occurred prior to the superframes 701. At the time of the DL guard transmission periods 723, the secondary devices 704-706 enter receive modes 738, 744, and 750 (TsRxWait), respectively, which means these secondary devices 704-706 are ready to receive transmissions from other device(s).

After the DL guard transmission period 723 expires, concurrent slot 711 begins. In slot 711, the primary device 703 (e.g., Main 1) broadcasts data 724 to the other devices 704 706. For example, the primary device 104-1 may broadcast data to one or more of the secondary devices 106 during slots 711. The data broadcast by the primary device 703 may include synchronization information that the receiving devices may use to synchronize their clocks with a clock of the primary device 703. For example, the data broadcast by the primary device 703 may include timestamp data that the receiving devices may use to synchronize their clocks with the clock of the primary device 703. The data broadcast by the primary device 703 may be referred to herein as downlinks. Numeral 725 indicates that, during transmission, the primary device 703 is in a transmission mode (TsMaxTx). At the same time, the secondary 704-706 are in receive modes 738, 744, and 750, respectively (TsRxWait). During slot 711, the primary device 703 switches from a transmit mode to a receive mode, as numeral 726 indicates (Tx2Rx).

In some examples, multiple primary devices 104 within the WBMS 100 implement concurrent superframe intervals. For example, a primary device 104-2 (labeled Main2 in FIG. 7) may broadcast synchronization data to the primary device 104-1 and to one or more of the secondary devices 106 during slot 712. In such examples, after transmission and receptions are complete in slot 712, the primary device 104-2 switches from a transmit mode to a receive mode. Concurrent superframe intervals can be beneficial in some examples by increasing the amount of time assigned to a given set of battery cells 108-1 per superframe interval. Examples of multiple primary devices 104 coordinating concurrent superframe intervals are described further in commonly assigned U.S. patent application Publication No. Ser. No. 19/213,653, which is incorporated by reference as described above.

Synchronization is complete in the example of FIG. 7 after slot 712. Slot 713 occurs after slot 712, during which multiple secondary devices simultaneously transmit data (e.g., status information collected from any of the battery cells 108) to the primary devices 703. For example, secondary device 704 may transmit data 743 to primary device 703. To enable such transmissions, secondary device 704 is in transmit mode 742 (TsMaxTx). To facilitate receptions of the transmitted data, primary device 703 is in receive mode 731 (TsRxWait). The data broadcast by secondary devices to primary devices may be referred to herein as uplinks.

Slot 714 occurs following slot 713, during which secondary device 705 transmits the data 747. Slot 715 occurs following slot 714, during which secondary device 706 switches from receive mode to transmit mode 753 (Rx2Tx). Although a single slot 715 is depicted between slots 714 and 716 in this example, any number of slots may be included between slots 714 and 716.

Slot 716 occurs following slot 715, during which secondary device 706 transmits data 755 to primary device 703 (while in receive mode 754, TsMaxTx). In some examples, the secondary device 706 already transmitted data 755 to primary device 703 during a prior slot between slots 714 and 716. Thus, by transmitting data 755 twice during different time slots, the risk of data loss is mitigated.

Redundant data transmissions need not occur in consecutive slots. Transmission of the same data in non-consecutive time slots can be beneficial, for example, if the passage of additional time between the slots facilitates the removal of a condition or physical obstacle that was preventing successful reception of the data in the first of the two time slots. The data transmission redundancy described above may be achieved if the datum is transmitted twice to the same primary device. For example, a particular datum may be transmitted to a first primary device, on a first frequency, and in a first superframe, and then again to the same first primary device, on a second frequency different than the first frequency, and in a second superframe concurrent with the first superframe. Data redundancy also may be achieved even if the datum is transmitted twice on the same frequency. For example, a particular datum may be transmitted to a first primary device, on a first frequency, and in a first superframe, and then again to a second primary device, on the same first frequency, and in a second superframe that is concurrent with the first superframe. Data redundancy also may be achieved even if the datum is transmitted twice on the same frequency and to the same primary device. For example, a particular datum may be transmitted to a first primary device, on a first frequency, and in a first superframe, and then again to the same first primary device, on the same first frequency, but in a second superframe concurrent with the first superframe. In other examples, a particular datum is transmitted twice in a given superframe interval, to differing primary devices, and on different frequencies. Any and all such variations are contemplated and included in the scope of this description.

To mitigate the risk of interference between simultaneous data transmissions, and further to mitigate the risk that same-data transmissions during separate slots fail to reach their destinations, secondary devices may use any of a variety of frequency hopping schemes. For example, with reference to timing diagram 700, in concurrent slots 713 and 719, the data 743 may be transmitted on a first frequency, and the data 776 may be simultaneously transmitted on a second frequency that is different than the first frequency. The first and second frequencies may be separated by at least 5 MHz or by at least 10 MHz (or, in terms of channels, the channels used are at least two channels, three channels, or five channels apart). Similarly, in concurrent slots 714 and 720, the data 743 and 776 may be simultaneously transmitted on first and second frequencies, respectively, with the first and second frequencies separated by at least 5 MHz or by at least 10 MHz (or, in terms of channels, the channels used are at least two channels, three channels, or five channels apart). Using different frequencies for simultaneous data transmission mitigates the risk of interference between the transmissions. Separation of at least 5 MHz or 10 MHz are examples of minimum separations; in some examples, the techniques of this description may be implemented with minimum frequency separation other than 5 MHz or 10 MHz. Techniques to ensure multiple primary devices 104 maintain at least a predetermined minimum frequency separation are described further in connection with FIG. 13.

Different frequencies also may be useful across different slots. For example, in timing diagram 700, a first frequency may be employed for transmissions in slot 713 and a second frequency may be employed for transmission in slot 714, where the first and second frequency are separated from one another by at least 5 MHz or by at least 10 MHz (or, in terms of channels, the channels used are at least two channels, three channels, or five channels apart). To facilitate such separation in transmission frequencies, primary devices (e.g., primary devices 104) may transmit in their downlinks to secondary devices (e.g., secondary devices 106) specific frequency hopping schemes that are to be used during data transmissions. Furthermore, in some examples, secondary devices may receive and transmit data on similar frequencies. For example, with reference to timing diagram 700, the secondary device 704 may receive data 724 in slot 711 on a first frequency, receive data 727 in slot 712 on a second frequency, and transmit data 743 in slot 713 on a third frequency. In some examples, the first and third frequencies may be the same.

As just one example, a primary device can use a frequency hopping sequence with thirty-seven channels in the industrial, scientific, and medical (ISM) band. These bands have a random order in the hopping sequence and satisfy the condition that the adjacent frequencies are separated by 5 MHz or by 10 MHz. For example, the first hopping sequence is {2410 MHZ, 2404 MHZ, 2416 MHZ, . . . } . The second hopping sequence can be a different version of the first hopping sequence, except shifted by one position. Hence, the second hopping sequence is {2404 MHz, 2416 MHz, . . . 2410 MHz}, preserving at least a 5 MHz separation or at least a 10 MHz separation for the primary device operating in a first frequency (2410 MHz) and another primary device operating in a second frequency (2404 MHz). After each hop, the first and second frequencies remain 5 MHz apart or 10 MHz apart.

In addition to transmitting frequency hopping schemes in downlinks, the primary devices 104 may transmit scheduling instructions to the secondary devices 106 in downlinks. For example, one or more primary devices 104 may be configured to instruct secondary devices 106 regarding the specific slots of a given superframe(s) and the specific channels or frequencies in which the secondary devices 106 are to transmit uplinks to the primary devices 104. The primary devices 104 may change the scheduling instructions with each superframe interval, or, alternatively, may maintain the same scheduling instructions for multiple consecutive superframe intervals. The primary devices 104 may also transmit additional information to the secondary devices 106, such as acknowledgements for uplink transmissions from a previous superframe, an indication when the next superframe may begin, an adaptive frequency hopping countdown, etc. In some examples, the primary devices 104 do not transmit scheduling instructions to the secondary devices 106 in the downlinks. Instead, some or all devices in the WBMS 100 are preprogrammed with a defined schedule that is to be followed for some or all superframe intervals, unless instructed otherwise by one or more primary devices 104. Alternatively, primary devices 104 may transmit a single downlink with scheduling instructions that are to be followed in all superframe intervals until further notice. The battery controller device 102 may provide the primary devices 104 with scheduling instructions that the primary devices 104 may then disseminate to the remaining devices of the WBMS 100.

The secondary devices 106 transmit data to the primary devices according to the scheduling instructions and channel or frequency instructions provided by the primary devices 104 or preprogrammed into the secondary devices. After receiving a downlink transmission from a primary device 104-1, a secondary device 106-2 may parse the transmission to determine the slots and channels or frequencies in which the secondary device 106-2 is scheduled to uplink information to the primary device(s). In some examples, information for how to parse the downlink transmission may be provided to the secondary device during a WBMS network formation process.

In some examples, secondary devices include multiple transceivers. For example, as shown in FIG. 2, the secondary device 106-1 includes multiple transceivers 128-1. Accordingly, the secondary device 106-1 may simultaneously (in the same slot) transmit data 743 twice using different transceivers 128-1. Such simultaneous transmissions may occur at the same or different frequencies. The transmissions may be directed to the same or different primary devices 104 (e.g., both the secondary and primary devices may have multiple transceivers communicating simultaneously on different frequencies). Thus, the same level of redundancy that is achieved by single-transceiver secondary devices transmitting the same data in different slots can be achieved by multi-transceiver secondary devices in a more compressed timeframe.

In some examples, uplink data transmissions may be performed in consecutive slots of concurrent superframes to accommodate large amounts of data that could not otherwise be transmitted in a single uplink. Such techniques are described in commonly assigned U.S. Application Publication No. 2025/0039859, entitled “Methods and Apparatus to Determine Communication Schedules for Wireless Battery Systems,” filed Jul. 28, 2023, which is hereby incorporated herein by reference in its entirety.

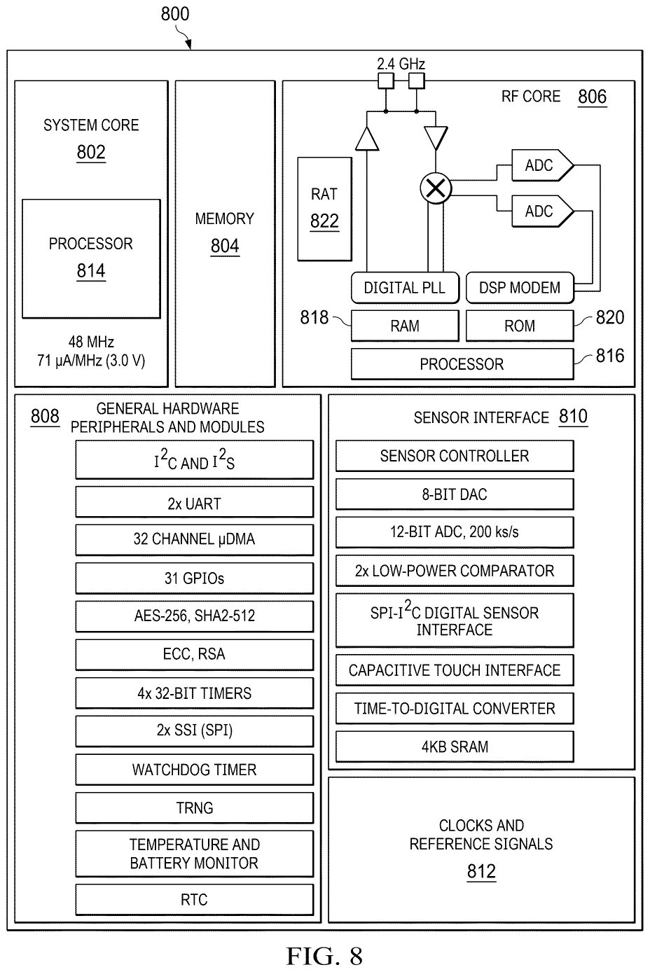

FIG. 8 is a block diagram of an example device 800. In the example of FIG. 8, the primary device 104 or secondary device 106 includes a system core (sys core) 802, a memory 804, a Radio Frequency core (RF core) 806, general hardware peripherals and modules 808, a sensor interface 810, and clocks and reference signals 812. In this example, the primary devices 104 and the secondary devices 106 of FIG. 6 are each implemented by one instance of the device 800 of FIG. 8. In some examples, one or more of the battery management device 102-1, the primary devices 104 or the secondary devices 106 are implemented with a different compute architecture.

The sys core 802 includes a processor 814 that is responsible for the system-level operations of the device 800. For example, when the device 800 is implemented with a primary device (e.g., 104-1), the processor 814 interprets instructions from the battery controller device 102-1, determines when and how to schedule superframe intervals, responds to the battery controller device 102-1 with EIS measurements and status updates, etc. Similarly, when the device 800 is implemented with a secondary device (e.g., 106-2), the processor 814 interprets instructions from one of the primary devices 106, determines when to respond within a superframe interval, determines what data to include in the response, etc. The processor 814 may be implemented by any type of programmable circuitry.

The sys core 802 performs system-level operations through the support of resources that are generally available to any component throughout the device 800. Such resources include but are not limited to the memory 804 and the clocks and reference signals 812. The speed at which a given operation are performed by the sys core 802 is dependent on a wide variety of factors that include but are not limited to: the role that the device 800 plays within the WBMS 100, the usage rates of system-level resources throughout the device 800, clock drift, etc. Operations performed by the sys core 802 therefore suffer from a system-level latency that is unique to a particular implementation of the device 800. For example, the sys core 802 in the secondary device 106-2 is likely to incur a different amount of system-level latency than the primary device 104-1 or the secondary device 106-3.

The RF core 806 refers to a group of components that operate independently of the sys core 802. For example, the RF core 806 includes a processor 816, RAM 818, ROM 820, and a Radio Timer (RAT) 822. As used herein, the RAT 822 refers to circuitry configured to generate a clock signal that is separate from the clocks and reference signals 812. The processor 816 performs operations with the support of the RAM 818, ROM 820, and RAT 822 and is therefore not reliant on other components outside of the RF core 806. As a result, operations performed by the RF core 806 do not exhibit the system-level latencies that are present when operations are performed by the sys core 802.

The RF core 806 is designed to perform radio operations (e.g., operations that implement wireless communication with other devices). However, the RF core 806 can also communicate with devices over wired communications by, for example, transmitting signals over the General Purpose Input Output (GPIO) pins or the Serial Peripheral Interface (SPI) pins within the general hardware peripherals and modules 808. In some examples, the RF core 806 is referred to as a communication circuit.

FIG. 9 is an illustrative example of timing signals that may be exchanged between devices in the WBMS of FIG. 6. The example of FIG. 9 includes a management device 902, a measurement device 904, a SPI interface 906, a GPIO interface 908, messages 910, 912, and 914, and a timeline. In this example, the management device 902 may be implemented by one or more of the primary device 104-1 or the secondary devices 106 of FIG. 6. Similarly, the measurement device 904 may be implemented by one or more of the module-level circuits BQ circuits 502 and the pack-level BQ circuits 604.

The management device 902 and the measurement device 904 are connected to one another through at least two wired connections, where the first wired connection implements the GPIO interface 908 and the second wired connection implements the SPI interface 906. In some examples, the management device 902 and the measurement device 904 are connected to one another through additional wired and/or wireless connections. In some examples, the GPIO interface 908 and/or the SPI interface 906 are implemented by interconnects, pins, ports, terminals, etc. in addition to or instead of wires.

FIG. 9 shows the management device 902 transmits a reference signal to the measurement device 904 over the GPIO interface 908. In this example, the pulses in the reference signal occur at T1, T2, and T3. As used herein, a pulse in a reference signal transmitted across a GPIO interface 908 may be referred to as a GPIO toggle. A given measurement device 904 performs multiple synchronization operations based on a GPIO toggle. First, the measurement device 904 starts an EIS measurement in response to receiving GPIO toggle. Second, the measurement device 904 uses the GPIO toggle as a reference point to adjust its internal clock based on the difference between a) a local timestamp generated by the measurement device 904 and b) a global timestamp that is reported by the management device 902. For example, the measurement device 904 receives the first GPIO toggle of FIG. 9 at T1. Suppose the internal clock of the measurement device 904 indicates T1=600 microseconds (μs) but a global timestamp from the management device 902 indicates T1=1.00 milliseconds (ms). In such an example, the management device 904 adjusts its internal clock by 400 μs after receiving the GPIO toggle so that it is synchronized with the rest of the module-level circuits BQ circuits 502 and the pack-level BQ circuits 604. As used above and herein, a global timestamp refers to a timestamp from a clock signal that is used globally throughout the WBMS 100 to perform operations (e.g., EIS measurements) synchronously. In some examples, a global timestamp is referred to as a reference timestamp because it can be used as a reference to perform clock adjustments. In some examples, the management device 902 transmits a reference signal to the measurement device 904 using a technique other than a GPIO interface 908.

The management device 904 also transmits one or more messages to the measurement device 904 over the SPI interface 906. The one or more messages from the SPI interface 906 describe the arrival of GPIO toggles using global timestamps. For example, suppose the reference signal of FIG. 9 is aperiodic such that the deltas between GPIO toggles (e.g., the values of (T2-T1) and (T3-T2)) are unequal. In such an example, the management device 902 transmits the message 910, which describes T1 using a global timestamp, to the measurement device 904 before T1. The measurement device 904 can extract the global timestamp from the message 910. The measurement device 904 stores the value from the message 910 in an internal register and then uses the value at T1 (e.g., upon receipt of the GPIO toggle) to adjust its internal clock as described above. Similarly, when the reference signal is aperiodic, the management device 904 transmits the message 912 before T2 to describe T2 using a global timestamp and transmits the message 914 before T3 to describe T3 using a global timestamp.

Alternatively, if the reference signal of FIG. 9 is periodic, the management device 902 only sends one message to describe both a) the first GPIO toggle using a global timestamp and b) the frequency of the periodic reference signal. For example, suppose the message 910 describes T1 with a global timestamp and indicates subsequent GPIO toggles will occur every 10 ms. In such an example, the messages 912 and 914 are not transmitted because the measurement device 904 can determine using only the message 910 that T2=T1+10 ms, T3=T1+20 ms, etc. In some examples, the management device 902 transmits one or more messages to the measurement device 904 using a technique other than a SPI interface 906.

The dual purpose of the reference signal (to use as a reference for EIS measurements internal clock synchronization) emphasize the need for management devices 904 across the WBMS 100 to transmit GPIO toggles as synchronously as possible with one another. Advantageously, the examples described herein utilize the RF core 806 of FIG. 8 to transmit the reference signal over the GPIO interface 908 while the sys core 802 simultaneously transmits messages over the SPI interface 906. In these examples, the timing of the messages 910, 912, 914 can tolerate some inaccuracies due to system-level latency because said messages only need to reach the corresponding measurement device 904 before T1, T2, or T3, respectively. In contrast, the timing of the reference signal is synchronized across the WBMS 100 to a higher degree of accuracy than the messages 910-914 because a) the RF core 806 does not have the system-level latencies of the sys core 802 and b) a GPIO pin can generally support higher degrees of speed and accuracy than a pin that implements a SPI protocol. Moreover, the use of the RF core 806 to transmit a reference signal via the GPIO interface 908 enables the examples described herein to be more accurate than known WBMS systems.

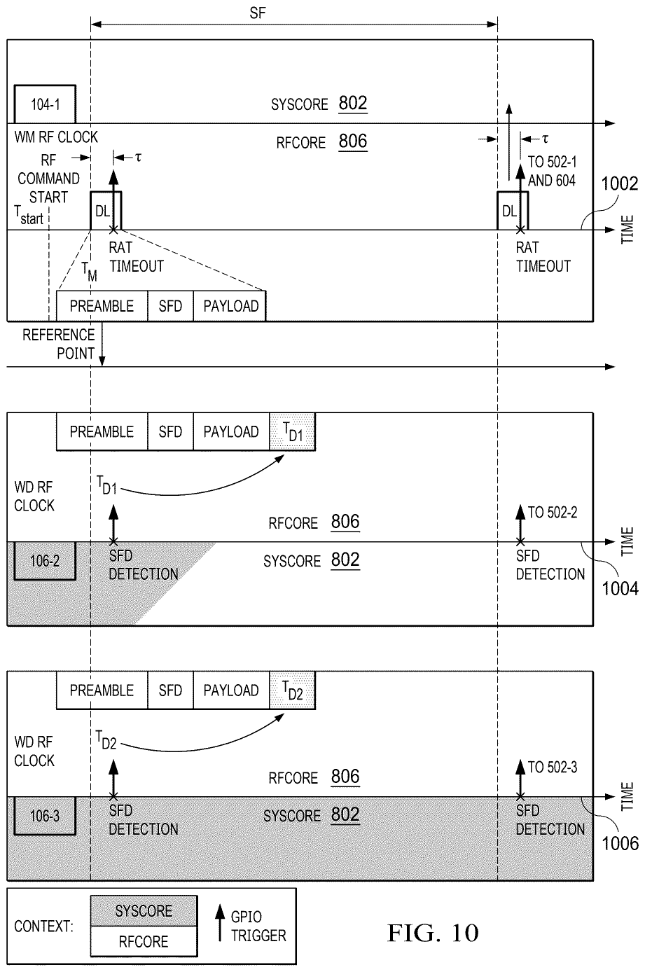

FIG. 10 is an illustrative example of a just-in-time protocol that may be implemented within the WBMS of FIG. 6. The example of FIG. 10 includes timelines 1002, 1004, and 1006 that correspond to example operations performed by the primary device 104-1, secondary device 106-2, and secondary device 106-3 respectively during a superframe (SF) interval.

The example of FIG. 10 begins at Tstart with a DL guard (e.g., 723 of FIG. 7A) that precedes the beginning of a superframe interval. After the DL guard, the RF command from the primary device 104-1 starts the superframe interval by transmitting a DL frame. The timeline 1002 shows that in this example, the DL frame includes a preamble, a Sync Frame Delimiter (SFD), and a payload.

The RF cores 806 of the secondary devices 106 receive the DL frame and then use the SFD as a reference point to synchronously trigger EIS measurements. To receive a DL frame, the RF cores 806 of the secondary device 106 demodulate a signal from a primary device 104 and extract data from the demodulated signal. In the example of FIG. 10, the RF cores 806 of the secondary devices 106 transmit a GPIO toggle to the respective BQ circuits 502 as soon as a SFD is detected. The RF cores of the secondary devices 106 may be configurable to transmit the GPIO toggle without involvement from (e.g., independently of) sys cores 802 and any software running on sys cores 802. The RF cores may also be configurable to transmit the GPIO toggle using only hardware in the RF cores, i.e., independently of any software running on the RF cores. For example, the timeline 1004 shows the secondary device 106-2 detects the SFD and transmits the GPIO toggle at TD1. Similarly, the timeline 1006 shows the secondary device 106-2 detects the SFD and transmits the GPIO toggle at TD2. In some examples, the operations of FIG. 10 are referred to as a just-in-time protocol because the secondary devices 106 receive the SFD just before the EIS measurements are scheduled to occur. In other examples, the RF cores 806 transmit a GPIO toggle to the respective BQ circuits 502 upon detection of a beginning portion of a packet along with or rather than upon detection of the SFD within the DL frame. As used herein, a beginning portion of a packet may refer to a SFD, a preamble, and/or another indication of the beginning of a packet.

Within the primary device 104-1, the RF core 806 also transmits a GPIO toggle to its respective BQ devices (e.g., 502-1 and 604) at the expiration of a timer implemented by the RAT 822. In the example of FIG. 10, the RAT timeout is annotated in the timeline 1002 as (RF command start+π). Advantageously, the differences in time between (RF command start+π) , T_{D1}, and TD2 are very small because the transmission of the SFD, reception of the SFD, and transmission of the GPIO toggle are all performed by the RF cores 806 and therefore avoid system-level latencies. More generally, the difference in time between GPIO toggles transmitted using the just-in-time protocol can support strict thermal runaway notification standards and are more accurate than known techniques.

The timelines 1004 and timelines 1006 show that within the secondary devices 106-2 and 106-3, the RF cores 806 modify their copies of the DL frame by appending a receipt time of the SFD (e.g., T_{D1} and T_{D2}, respectively) to the end of the frame. The RF cores 806 then transmit the modified DL frames to their corresponding sys cores 802. The Sys cores 802 use the reported values of T_{D1} and T_{D2} to reduce clock drift from the clocks and reference signals 812, thereby preventing the effects of system-level latency from accumulating. In some examples, a sys core 802 also uses the timestamp describing SFD detection to prepare a response for its allotted slot(s) of the superframe (e.g., the timestamps are used to organize and/or generate data that comprises the response). The sys core 802 may be configurable to generate the timestamp in response to receiving the DL frame, and the timestamp may indicate a receipt time of the SFD in the DL frame.

In the example of FIG. 10, the reference signal sent to the module-level BQ circuits 502 and the pack-level BQ device 604 is periodic. Accordingly, the foregoing operations repeat at regular timing intervals and the devices of FIG. 10 transmit GPIO toggles during the DL frames at the start of the next superframe interval.

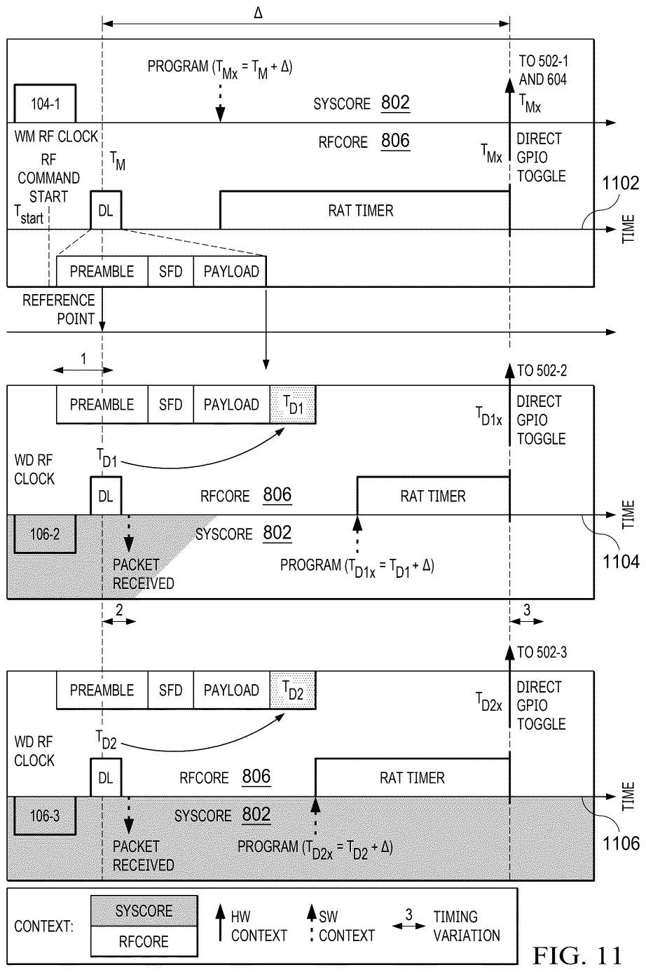

FIG. 11 is a first illustrative example of a schedule protocol that may be implemented within the WBMS of FIG. 6. The example of FIG. 11 includes timelines 1102, 1104, and 1106 that correspond to example operations performed by the primary device 104-1, secondary device 106-2, and secondary device 106-3 respectively during a superframe (SF) interval.

FIG. 11 shows that the primary device 104-1 transmits a DL frame containing a SFD at the start of a superframe interval in both the just-in-time protocol and the schedule protocol. However, in the schedule protocol, the Sys core 802 uses the timestamp of the SFD to schedule the transmission of a GPIO toggle at a later point in time. For example, the timeline 1104 shows the sys core 802 within the secondary device 106-2 instructs the RF core 806 to transmit the GPIO toggle at (T_{D1x}=T_{D1}+Δ) and A refers to the amount of time between consecutive GPIO toggles. Upon receipt of the instruction, the RF core 806 within the secondary device 106-2 starts a timer with the RAT 822 that expires at T_{D1x}. The RF core 806 the GPIO toggle upon expiration of the RAT timer. Similarly, the timeline 1106 shows the sys core 802 shows the sys core 802 within the secondary device 106-3 instructs the RF core 806 to transmit the GPIO toggle at (T_{D2x}=T_{D2}+Δ), and the RF core 806 sets a timer to expire at T_{D2x}. The timeline 1102 also shows the RF core 806 in the primary device 104-1 sets its RAT 822 to expire at T_{Mx} based on a preceding instruction from the corresponding sys core 802.

In both the just-in-time protocol of FIG. 10 and the schedule protocol of FIG. 11, the difference in time between the SFD and the expiration of a RAT 822 is generally less than 100 nano seconds (ns). Accordingly, clock drift from the RATs 822 that occur over such a short duration is generally considered negligible and the timestamps T_{Mx}, T_{D1x} and T_{D1x} occur synchronously (e.g., at the same time as one another) to a high degree of accuracy. In the schedule protocol, the value of T_{D1x} and T_{D1x} are determined in part by the sys core 802. In the example of FIG. 11, the timelines 1104 and 1106 show that system-level latencies cause the sys cores 802 in the secondary device 106-2 and 106-3 to send their TD1x and TD2x instructions to the corresponding RF cores 806 at different times. Advantageously, the RF cores 806 set their RATs 822 to different values so that both times expire at the same time. More generally, the use of the RAT 822 enables the GPIO tool to be transmitted independently of system-level latencies even when the sys core 802 is involved in preceding operations. Accordingly, the schedule protocol described in examples herein offers flexibility (e.g., synchronous GPIO toggles can occur not just at the start of a superframe but at any time) while still being highly accurate to support strict thermal runaway notification standards.

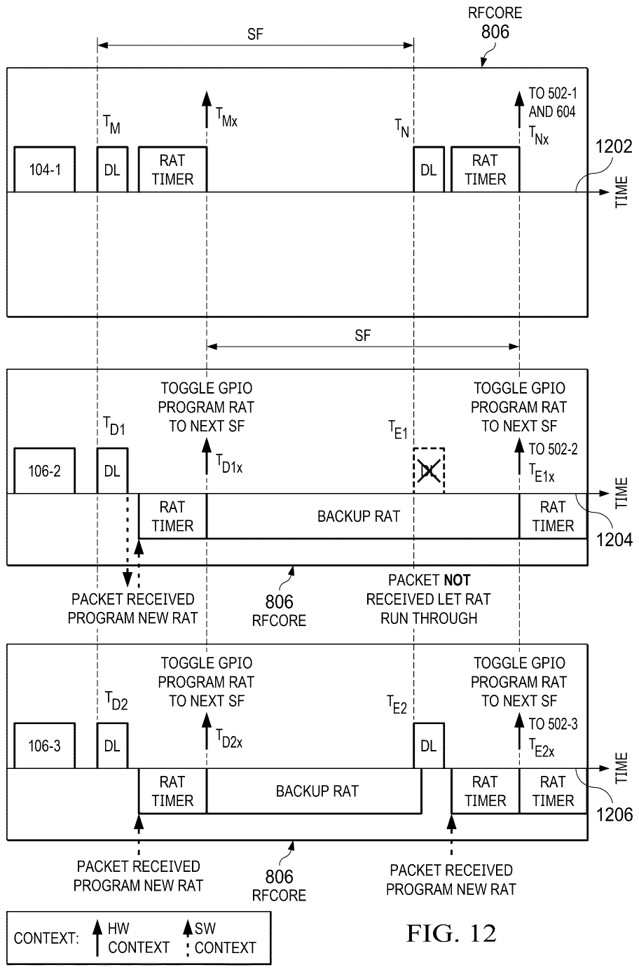

FIG. 12 is an illustrative example of backup timers that may be employed within the just-in-time protocol of FIG. 10 or the schedule protocol of FIG. 11. The example of FIG. 12 includes timelines 1202, 1204, and 1206 that correspond to example operations performed by the RF cores 806 of the primary device 104-1, secondary device 106-2, and secondary device 106-3 respectively during a superframe (SF) interval.

Both the just-in-time protocol and the schedule protocol cause a management device 902 of FIG. 9 to transmit a GPIO toggle based on an SFD. However, in some examples, a secondary device 106 drops a packet and does not receive the DL frame to the volatile nature of wireless communications. Advantageously, the RF cores 806 in the secondary devices 106 utilize the RAT 822 to set back-up timers in case a DL frame is dropped. For example, the timelines 1204 and 1206 show that both the secondary device 106-2 and 106-3 receive the DL frame at T_{D1}=T_{D2}, set the RAT 822 to expire at T_{D1x}=T_{D2x}, and transmit a GPIO toggle upon the expiration of the RAT 822. After the transmission of the GPIO toggle RAT 822, both secondary devices 106-2 and 106-3 reset their RAT 822 to a new value that expires when the RF cores 806 expect the next GPIO toggle transmission to occur. In some examples, such a timer value is referred to as a backup RAT.

In the example of FIG. 12, the timeline 1206 shows the secondary device 106-3 successfully receiving the next DL frame at T_{E2}. Accordingly, the RF core 806 in the secondary device 106-3 cancels the backup RAT at T_{E2} and, based on the schedule protocol, sets a new timer value in the RAT 822 to expire at T_{E2x}. In contrast, the timeline 1204 shows the secondary device 106-1 was supposed to receive the next DL frame at T_{E1}=T_{E2} but failed to do so. Accordingly, the RF core 806 allows the backup RAT originally set at T_{D1x} to continue running past T_{E1} and into the next superframe interval. The backup RAT in the timeline 1204 expires at T_{E1x}=T_{E2x}, thereby allowing the secondary device 106-2 to synchronously transmit its GPIO toggle with a high degree of accuracy despite failing to receive the SFD.

While FIG. 12 shows an example implementation of the schedule protocol of FIG. 11, the use of a backup RAT to safeguard against dropped DL frames can also be applied to the just-in-time protocol of FIG. 10. In such an example, the back-up RAT begins immediately after an SFD is received/GPIO toggle is transmitted and is set to expire when the RF core 806 expects the next SFD to occur. If the RF core 806 receives the next SFD before the expiration of the backup RAT, then the backup RAT is cancelled and the GPIO toggle is transmitted upon receipt of the SFD. Alternatively, if the RF core 806 fails to receive the next SFD, the RF core 806 still transmits the GPIO toggle at the expiration of the backup RAT. Thus, the use of the RAT 822 as a backup in either protocol described in examples herein mitigates the relative unreliability of wireless communication and ensures a given secondary device 106 transmits a GPIO toggle when it is scheduled to do so. Moreover, if minimal clock drift in the RAT 822 occurs because the loss of a DL frame also represents a failure to resynchronize, the drift is quantified by the RF core 806 through the timestamps (e.g., T_{D1}) in the modified DL frame and reported to the system core 802 so the WBMS 100 can respond accordingly.

In some examples, a primary device 104-1 transmits a DL frame in each superframe interval regardless of the content of the superframe or how many secondary devices 106 successfully receive the DL. Such examples may be referred to as active mode. In active mode, a primary device 104-1 and corresponding secondary device 106-2 may declare a sync loss and perform synchronization operations if the secondary device 106-2 fails to receive the DL frame a threshold number of consecutive times (e.g., 16 failures in a row). In other examples, the primary device 104-1 does not send a DL frame in every superframe interval but instead includes DL frames at a lower frequency (e.g., once every 300 ms). This lower frequency may be referred to as a Keep Alive Interval (KAI) in some examples.

In addition to timing accuracy, another advantage of utilizing a RAT 822 as described above is that the RF core 806 automatically handles power management to minimize the power consumption. For example, if the expiration of a timer set on the RAT 822 is sufficiently far into the future, the RF core 806 will put itself in low power mode while waiting for the timer to expire. In some examples, the RAT 822 is turned off during low power operation, but the RAT 822 is calibrated by a Real Time Clock (RTC) and has an expected accuracy of one to two RAT clock cycles upon powerup.

Low power mode generally has a larger impact on the sys core 802 than the RF core 806. In such examples, software execution timing is likely to be delayed during the wakeup process. Accordingly, in examples where software execution from the sys core 802 is required, the software sets power constraints that prevent the sys core 802 from entering low power (e.g., standby) mode to ensure timing accuracy.

FIG. 13 is an illustrative example of the performance of the just-in-time protocol of FIG. 10. Similarly, FIG. 14 is an illustrative example of the performance of the schedule protocol of FIG. 11. Both FIGS. 13 and 14 show examples where there are two secondary devices 106 per primary device 104 and where the superframe interval is 6 ms. In the example of FIG. 13, GPIO toggles are transmitted on SFD detection according to the just-in-time protocol. In the example of FIG. 14, GPIO toggles are transmitted after 5 ms when the RAT 822 times out according to the schedule protocol.

Both FIGS. 13 and 14 also show a) a GPIO signal transmitted from the secondary device 106-2 to the BQ circuit 502-2 and b) a GPIO signal transmitted from the secondary device 106-3 to the BQ circuit 502-3. In the examples FIGS. 13 and 14, a GPIO toggle as described above occurs on both a falling edge and a rising edge of a GPIO signal. Accordingly, in both examples, the foregoing signals show synchronized GPIO toggles occur less than 1 μs away from one another. More generally, FIGS. 13 and 14 show both the just-in-time protocol and the schedule protocol can be used to synchronously perform EIS measurements to a high degree of accuracy, which promotes reliable measurements of battery characteristics.

FIG. 15 is a flowchart representative of example machine-readable instructions and/or example operations 1500 that may be at least one of executed, instantiated, or performed by the primary device 104 of FIG. 6. While the following description of FIG. 15 is in reference to the primary device 104-1, the machine-readable instructions and/or the example operations 1500 of FIG. 15 may be implemented by any of the primary devices 104 in the WBMS 100. The flowchart of FIG. 15 begins when the RF core 806 of a primary device 104-1 optionally transmits a SPI message that indicates when battery measurement(s) are scheduled. (Block 1502). To do so, the RF core 806 generates an SPI message that describes when one or more upcoming GPIO triggers will be transmitted. The reception of the SPI message and subsequent operations are described further in connection with FIG. 18. In examples where the GPIO toggles are periodic, the primary device 104-1 may execute block 1502 only once by sending a SPI message that describes a) a timestamp of the first GPIO toggle and b) the frequency of subsequent GPIO toggles. In examples where the GPIO toggles are not periodic, the primary device 104-1 executes block 1502 once per iteration of the FIG. 15 flowchart.

The RF core 806 of the primary device 104-1 transmits a Sync Frame Delimiter (SFD) within the Downlink (DL) frame at the start of a superframe interval. (Block 1504). The DL frames are transmitted over a wireless interface to one or more secondary devices (e.g., 106-2 and 106-3 in FIG. 6). The DL frame of block 1504 may contain additional information as described above in FIGS. 7A, 7B, and 10. In some examples, the transmission of the DL frame at block 1504 is referred to as a downlink communication.

The sys core 802 of the primary device 104-1instructs the RF core 806 to transmit a GPIO toggle at a particular timestamp. (Block 1506). In the just-in-time protocol, the timestamp describes when the sys core 802 expects the secondary devices 106 to receive the SFD of block 1504. In the schedule protocol, the timestamp refers to a point in time that is after the reception of the SFD but before the end of the current superframe interval.

The RF core 806 of the primary device 104-1 sets the RAT 822 with a timer value that expires at the timestamp of block 1506. (Block 1508). Advantageously, the RAT 822 is used exclusively by other components within the RF core 806 and therefore does not exhibit the system-level latencies of the sys core 802.

The RF core 806 of the primary device 104-1 determines whether the RAT 822 has expired. (Block 1510). If the RAT has not yet expired (Block 1510: No), control returns to block 1510 where the RF core 806 rechecks the RAT 822 after an amount of time (e.g., after one or more clock cycles). In some examples, the RF core 806 enters a low power mode between subsequent iterations of block 1510 as described above. If the RAT has expired (Block 1510: Yes), the RF core 806 then transmits a GPIO toggle to one or more BQ circuits 502. (Block 1512). The RF core 806 transmits the GPIO toggle to prompt or cause a battery monitor circuit to perform a measurement and other operations as described further in connection with FIG. 18. The battery monitor circuit may be configurable to perform the measurement in response to receiving the GPIO toggle.

The sys core 802 of the primary device 104-1 determines whether to continue. (Block 1514). In some examples, the sys core 802 continues whenever the primary device 104-1 is powered on. In other examples, the sys core 802 only continues during measurement windows that are defined by the battery controller device 102-1. The machine-readable instructions and/or the operations 1500 end if the sys core 802 does not continue. (Block 1514: No). Alternatively, if the sys core 802 does continue (Block 1514: Yes), control returns to block 1502 where the RF core 806 optionally transmits another SPI message.

While the foregoing description of FIG. 15 was in reference to the primary device 104-1, the machine-readable instructions and/or the operations 1500 of FIG. 15 may also be implemented by the battery controller device 102-1 of FIG. 6. In such examples, the BQ pack-level device 604 receives the SPI message of block 1502 and the GPIO toggle of block 1512 instead of a module-level BQ circuit 502-1. The GPIO toggle may prompt the BQ pack-level device 604 to perform a measurement.

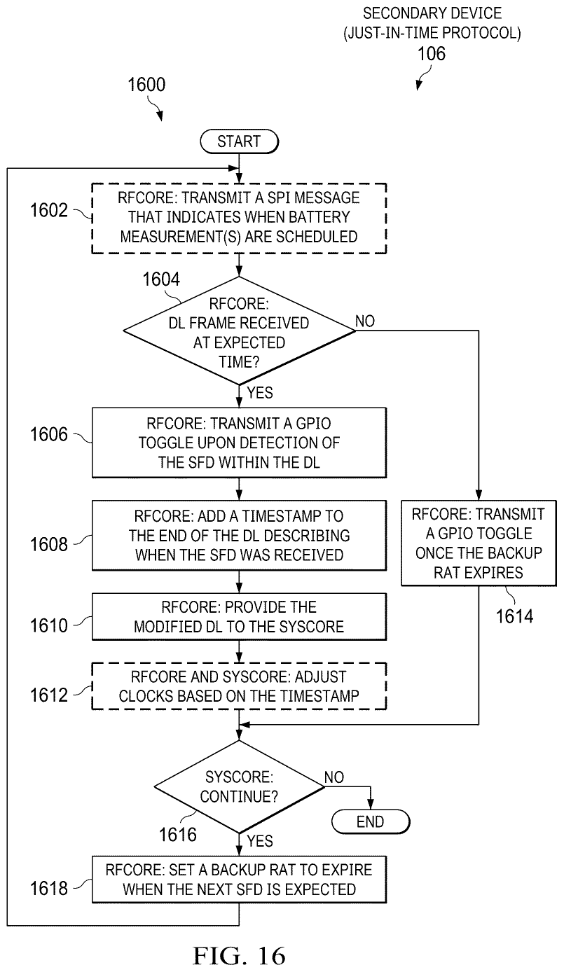

FIG. 16 is a flowchart representative of example machine-readable instructions or example operations that may be at least one of executed, instantiated, or performed by a secondary device of FIG. 6 to implement the just-in-time protocol. While the following description of FIG. 16 is in reference to the secondary device 106-2, the machine-readable instructions and/or the example operations 1600 of FIG. 16 may be implemented by any of the secondary devices 106 in the WBMS 100.

Execution of FIG. 16 begins when the RF core 806 of the secondary device 106-2 optionally transmits a SPI message that indicate when battery measurement(s) are scheduled. (Block 1602). The secondary device 106-2 optionally executes block 1602 using the same techniques and logic described above in connection with block 1502 of FIG. 15.

The RF core 806 of the secondary device 106-2 determines whether a DL frame was received at an expected time. (Block 1604). The RF core 806 determines the expected time of block 1604 based on a) previous instructions from the primary device 104-1 and/or b) the timing of previous superframe intervals. If the DL frame is received at the expected time (Block 1604: Yes), the RF core 806 within the secondary device 106-2 transmits a GPIO toggle upon detection of the SFD within the DL frame. (Block 1606). The reception of the GPIO toggle and subsequent operations are described further in connection with FIG. 18. In some examples, the RF core 806 also cancels a backup RAT at block 1606 as described further below.

The RF core 806 of the secondary device 106-2 adds a timestamp to the end of the DL frame describing when the SFD was received. (Block 1608). The RF core 806 then provides the modified DL frame of block 1608 to the sys core 802 of the secondary device 106-2. (Block 1610). The timestamp of block 1608 allows both the RF core 806 and the sys core 802 to optionally adjust their clocks. (Block 1612). For example, the RF core 806 may adjust clock generation circuitry that powers the RAT 822, and/or the sys core 802 may adjust one or more system-level clock signals, based on a difference between an expected and an actual value of the timestamp.

Alternatively, if the RF core 806 of the secondary device 106-2 does not receive the DL frame at the expected time (Block 1604: No), the RF core 806 transmits the GPIO toggle once a timer set on the RAT 822 expires. (Block 1614). In the example of FIG. 16, the timer set on the RAT 822 is referred to as a backup RAT because it does not expire in the expected program execution path of (block 1604: Yes) through block 1612.

The sys core 802 of the secondary device 106-2 determines whether to continue. (Block 1616). The sys core 802 executes block 1616 using the same techniques and logic as described above at block 1514 of FIG. 15.

The machine-readable instructions and/or the operations 1600 end if the sys core 802 does not continue. (Block 1616: No). Alternatively, if the sys core 802 does continue (Block 1616: Yes), the RF core 806 sets the backup RAT to expire when the next SFD is expected. (Block 1618). The RF core 806 of the secondary device 106-2 may determine when to expect to receive the next SFD based on a) instructions from the battery controller device 102 and/or b) the timing of previous superframe intervals. Control then returns to block 1602 where the RF core 806 of the secondary device 106-2 optionally transmits a SPI message.

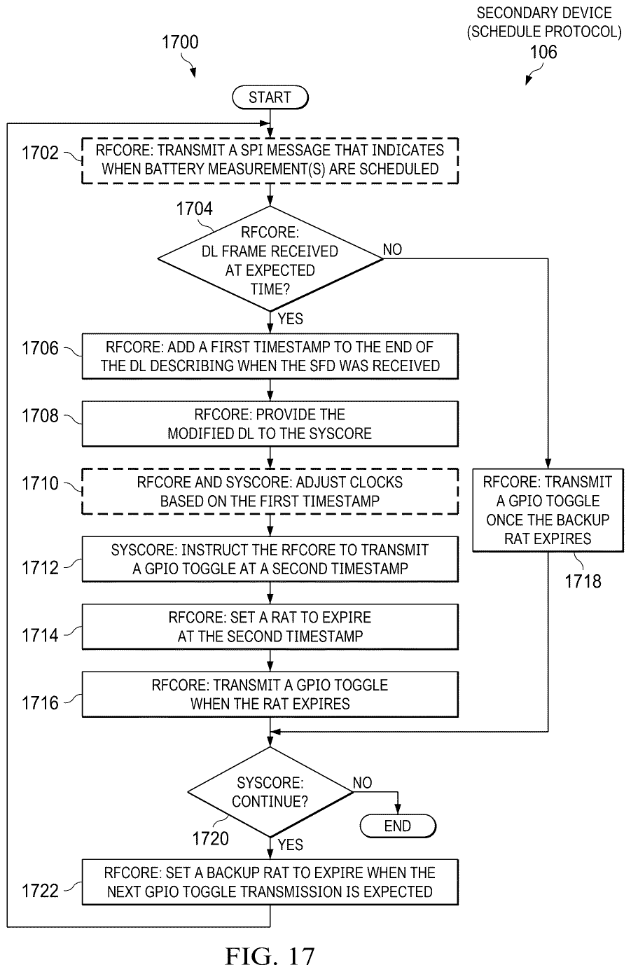

FIG. 17 is a flowchart representative of example machine-readable instructions or example operations that may be at least one of executed, instantiated, or performed by a secondary device of FIG. 6 to implement the schedule protocol. While the following description of FIG. 16 is in reference to the secondary device 106-2, the machine-readable instructions and/or the example operations 1700 of FIG. 17 may be implemented by any of the secondary devices 106 in the WBMS 100.

Execution of FIG. 17 begins when the RF core 806 of the secondary device 106-2 optionally transmits a SPI message that indicate when battery measurement(s) are scheduled. (Block 1702). The secondary device 106-2 optionally executes block 1702 using the same techniques and logic described above in connection with block 1502 of FIG. 15.

The RF core 806 of the secondary device 106-2 determines whether a DL frame was received at an expected time. (Block 1704). If the DL frame is received at the expected time (Block 1704: Yes), the RF core 806 adds a first timestamp to the end of the DL frame describing when the SFD was received (Block 1706) and then provides the modified DL to the sys core 802. (Block 1708). The first timestamp allows both the RF core 806 and the sys core 802 to optionally adjust their clocks (Block 1710). The secondary device 106-2 executed blocks 1704, 1706, 1708, and 1710 using the same techniques and logic as blocks 1604, 1608, 1610, and 1612, respectively. In some examples, the RF core 806 also cancels a backup RAT at block 1706 as described further below.

The sys core 802 of the secondary device 106-2 instructs the RF core 806 to transmit a GPIO toggle at a second timestamp. (Block 1712). The second timestamp occurs after the first timestamp (e.g., after detection of the SFD) but before the current superframe interval ends. In some examples, the sys core 802 determines the value of the second timestamp based on instructions from the battery controller device 102-1. Moreover, the one or more secondary devices 106 executing FIG. 17 select the same value for the second timestamp at block 1712 to ensure synchronous EIS measurements.

The RF core 806 of the secondary device 106-2 sets the RAT 822 to expire at the second timestamp. (Block 1714). Advantageously, the RAT 822 of block 1714 maintains synchronous EIS measurements even if the multiple secondary devices 106 execute block 1712 at different times due to differing system-level latencies.

The RF core 806 of the secondary device 106-2 transmits a GPIO toggle when the RAT expires. (Block 1716). The reception of the GPIO toggle and subsequent operations are described further in connection with FIG. 18.

Alternatively, if the RF core 806 of the secondary device 106-2 does not receive the DL frame at the expected time (Block 1704: No), the RF core 806 transmits the GPIO toggle once a backup timer set on the RAT 822 expires. (Block 1718). The timer of block 1718 is referred to as a backup in this example because a) it is separate from the timer that runs from block 1714 to block 1716 and b) the timer of block 1718 does not expire in the expected program execution path of (Block 1704: Yes) through block 1720. In some examples, the RF core 806 enters a low power mode between the failure to receive a DL frame (block 1704: No) and the expiration of the backup RAT at block 1718.

The sys core 802 of the secondary device 106-2 determines whether to continue. (Block 1720). The sys core 802 executes block 1720 using the same techniques and logic as described above at block 1514 of FIG. 15.

The machine-readable instructions and/or the operations 1600 end if the sys core 802 does not continue. (Block 1720: No). Alternatively, if the sys core 802 does continue (Block 1720: Yes), the RF core 806 sets the backup RAT to expire when the next GPIO toggle transmission is expected. (Block 1722). The RF core 806 of the secondary device 106-2 may determine when to expect execution of the next iteration of block 1716 based on a) instructions from the battery controller device 102 and/or b) the timing of previous superframe intervals. Control then returns to block 1702 where the RF core 806 of the secondary device 106-2 optionally transmits a SPI message.

FIG. 18 is a flowchart representative of example machine-readable instructions or example operations 1800 that may be at least one of executed, instantiated, or performed using an example programmable circuitry implementation of a measurement device 904 of FIG. 9. The flowchart of FIG. 18 may be implemented by any of the module-level BQ circuits 502 and/or the pack-level BQ circuits 604.

The machine-readable instructions or operations 1800 begin when the measurement device 904 optionally receives a SPI message. (Block 1802). In some examples, the measurement device 904 receives one message at block 1802 per iteration of the flowchart of FIG. 18 when the GPIO toggles are not periodic. In other examples, the measurement receives one message total at the start of a sequence of periodic GPIO toggles.

The measurement device 904 determines whether a GPIO toggle has been received. (Block 1804). The GPIO toggle may be transmitted by any appropriate implementation of the management device (e.g., the battery controller device 102-1, one of the primary devices 104, one of the secondary devices 106, etc.). If a GPIO toggle has not been received (Block 1804: No), control returns to block 1804 where the measurement device 904 checks for a GPIO toggle again after an amount of timer.

If a GPIO toggle has been received (Block 1804: Yes), the measurement device 904 performs one or more battery measurement operations. (Block 1806). The measurements may be module-level or pack-level measurements depending on the type of device implementing the flowchart of FIG. 18. In some examples, the measurements of block 1806 are EIS measurements.

The measurement device 904 reports the results of the battery measurement operations to the management device 902. (Block 1808). The corresponding measurement values may be reported in any suitable format and over any suitable medium depending on the architecture of the WBMS 100.

The measurement device 904 performs one or more clock synchronization operations. (Block 1810). To do so, the measurement device 904 compares when the GPIO toggle of block 1804 was actually received to when the measurement device 904 expected it to be received based on its internal clock. The measurement device 904 determines when it expects an upcoming GPIO toggle to be received based on the one or more SPI messages received previously at block 1802.

The measurement device 904 determines whether to continue. (Block 1812). In some examples, the measurement device 904 continues whenever the device is powered on. If the measurement device 904 continues (Block 1812: Yes), control returns to block 1802 where the measurement device 904 optionally receives another SPI message. If the measurement device 904 does not continue (Block 1812: No), the machine-readable instructions and/or operations 1800 end.

FIG. 19 is a block diagram of an example programmable circuitry platform 1900 structured to one or a combination of execute or instantiate one or more of the example machine-readable instructions or the example operations of FIGS. 15-18 to implement the WBMS 100 of FIG. 6. The programmable circuitry platform 1900 can be, for example, a server, a personal computer, a workstation, an Electronic Control Unit (ECU), or any other type of computing or electronic device. In this example, the programmable circuitry platform implements one or more of the battery controller devices 102, the primary devices 104, or the secondary devices 106.

The programmable circuitry platform 1900 of the illustrated example includes programmable circuitry 1912. The programmable circuitry 1912 of the illustrated example is hardware. For example, the programmable circuitry 1912 can be implemented by one or more integrated circuits, logic circuits, FPGAs, microprocessors, CPUs, GPUs, DSPs, or microcontrollers from any desired family or manufacturer. The programmable circuitry 1912 may be implemented by one or more semiconductor based (e.g., silicon based) devices.

The programmable circuitry 1912 of the illustrated example includes a local memory 1913 (e.g., a cache, registers, etc.). The programmable circuitry 1912 of the illustrated example is in communication with main memory 1914, 1916, which includes a volatile memory 1914 and a non-volatile memory 1916, by a bus 1918. The volatile memory 1914 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 1916 may be implemented by one or a combination of flash memory or any other desired type of memory device. Access to the main memory 1914, 1916 of the illustrated example is controlled by a memory controller 1917. In some examples, the memory controller 1917 may be implemented by one or more integrated circuits, logic circuits, microcontrollers from any desired family or manufacturer, or any other type of circuitry to manage the flow of data going to and from the main memory 1914, 1916.

The programmable circuitry platform 1900 of the illustrated example also includes interface circuitry 1920. The interface circuitry 1920 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1922 are connected to the interface circuitry 1920. The input device(s) 1922 permit(s) a user (e.g., a human user, a machine user, etc.) to enter one or a combination of data or commands into the programmable circuitry 1912. The input device(s) 1922 can be implemented by, for example, one of or a combination of a battery cell, a monitor circuit, an excitation source, or another controller device.

One or more output devices 1924 are also connected to the interface circuitry 1920 of the illustrated example. The output device(s) 1924 can be implemented by, for example, one of or a combination of a battery cell, a monitor circuit, an excitation source, or another controller device. The interface circuitry 1920 of the illustrated example, thus, includes one or a combination of a graphics driver card, a graphics driver chip, or graphics processor circuitry such as a GPU.

The interface circuitry 1920 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 1926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1900 of the illustrated example also includes one or more mass storage discs or devices 1928 to store one or more of firmware, software, or data. Examples of such mass storage discs or devices 1928 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 1932, which may be implemented by the machine-readable instructions of FIGS. 15-18 , may be stored in one of or a combination of the mass storage device 1928, in the volatile memory 1914, in the non-volatile memory 1916, or on at least one non-transitory computer readable storage medium such as a CD or DVD which may be removable.

While an example manner of implementing the WBMS 100 of FIG. 1 is illustrated in FIG. 6, one or more of the elements, processes, or devices illustrated in FIG. 6 may be combined, divided, re-arranged, omitted, eliminated, or implemented in any other way. Further, the battery controller device 102-1, the primary devices 104, the secondary devices 106, the BQ circuits 502, the excitation source 602, the BQ pack-level device 604, or, more generally, the example WBMS 100 of FIG. 6, may be implemented by hardware alone or by hardware in combination with software and firmware. Thus, for example, any of the battery controller device 102-1, the primary devices 104, the secondary devices 106, the BQ circuits 502, the excitation source 602, the BQ pack-level device 604, or, more generally, the example WBMS 100, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example WBMS 100 of FIG. 6 may include one or more elements, processes, or devices in addition to, or instead of, those illustrated in FIG. 6, or may include more than one of any or all of the illustrated elements, processes and devices.

Flowchart(s) representative of example machine-readable instructions, which may be executed by programmable circuitry to at least one of implement or instantiate the WBMS 100 of FIG. 6 or representative of example operations which may be performed by programmable circuitry to at least one of implement or instantiate the WBMS 100 of FIG. 6, are shown in FIGS. 15-18 . The machine-readable instructions may be one or more executable programs or portion(s) of one or more executable programs for execution by programmable circuitry such as the programmable circuitry 1912 shown in the example programmable circuitry platform 1900 discussed below in connection with FIG. 19 and may be one or more function(s) or portion(s) of functions to be performed by the example programmable circuitry (e.g., an FPGA). In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 15-18 , many other methods of implementing the example WBMS 100 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, one of or a combination of a CPU or an FPGA. The programmable circuitry may include one or more CPUs and/or one or more FPGAs located in the same package (e.g., the same integrated circuit (IC) package or in two or more separate housings), one or more CPUs or FPGAs in a single machine, one or multiple CPUs or FPGAs distributed across multiple servers of a server rack, multiple processors distributed across one or more server racks. Also or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., or any combination(s) thereof in any of the contexts explained above.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 15-18 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” may be understood to include (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

From the foregoing, it will be appreciated that example systems, apparatus, articles of manufacture, and methods have been described that herein perform EIS measurements with a high degree of accuracy that is agnostic to system-level latency and supports struct thermal runaway notification standards. Described systems, apparatus, articles of manufacture, and methods improve the efficiency of using a computing device by synchronizing battery measurements and adjusting internal clock signals based on a reference signal composed of GPIO toggles, and by transmitting the GPIO toggles with a RF core that is separate and independent from system-level compute resources. Described systems, apparatus, articles of manufacture, and methods are also directed to one or more improvement(s) in the operation of a machine such as a computer or other electronic, electromechanical, or mechanical device.

What is claimed is:

1. A device comprising:
a wireless receiver configurable to receive a packet;
a programmable circuit; and
a communication circuit coupled to the wireless receiver and the programmable circuit, wherein the communication circuit is configurable to:
identify a portion of the packet; and
cause the device to send a first wired signal to a battery monitor circuit in response to identifying the portion of the packet.

2. The device of claim 1, wherein to identify the portion of the packet, the communication circuit is configurable to identify a sync frame delimiter in the packet.

3. The device of claim 1, wherein to identify the portion of the packet, the communication circuit is configurable to identify a beginning portion in the packet.

4. The device of claim 1, wherein the communication circuit is configurable to cause the device to send the first wired signal to prompt the battery monitor circuit to perform a measurement of a battery.

5. The device of claim 4, wherein the communication circuit is configurable to cause the device to send the first wired signal to prompt the battery monitor circuit to perform the measurement of the battery upon receipt of the first wired signal by the battery monitor circuit.

6. The device of claim 1, wherein the communication circuit is configurable to identify the portion of the packet and cause the device to send the first wired signal independently of software executed by the programmable circuit.

7. The device of claim 6,
wherein the wireless receiver is configurable to receive a signal encoding the packet,
wherein the communication circuit is configurable to demodulate the signal received by the wireless receiver, and
wherein the programmable circuit is configurable to extract data from the demodulated signal.

8. The device of claim 1, wherein the programmable circuit is configurable to send a second wired signal to the battery monitor circuit in response to receiving the packet.

9. The device of claim 8, wherein the programmable circuit is configurable to send the second wired signal via a serial peripheral interface.

10. The device of claim 9, wherein the communication circuit is configurable to send the first wired signal via a general purpose input/output interface.

11. The device of claim 1, wherein the communication circuit is configurable to:
generate a first timestamp indicating a receipt time of the portion of the packet; and
report the first timestamp to the programmable circuit.

12. The device of claim 11, wherein the programmable circuit is configurable to:
extract a reference timestamp from the packet;
compare the reference timestamp to the first timestamp; and
adjust an internal clock in response to comparing the reference timestamp to the first timestamp.

13. The device of claim 1,
wherein the device is a secondary wireless device in a battery management system, and
wherein the wireless receiver is configured to receive the packet as a downlink communication from a primary wireless device in the battery management system.

14. A device comprising:
a wireless receiver configurable to receive a packet;
a programmable circuit; and
a communication circuit coupled to the wireless receiver and the programmable circuit, wherein the communication circuit is configurable to:
set a timer in response to the packet; and
cause the device to send a first wired signal to a battery monitor circuit at an expiration of the timer.

15. The device of claim 14, wherein the communication circuit is configurable to cause the device to send the first wired signal to prompt the battery monitor circuit to perform a measurement of a battery upon receipt of the first wired signal by the battery monitor circuit.

16. The device of claim 14, wherein the communication circuit is configurable to set the timer and cause the device to send the first wired signal independently of software executed by the programmable circuit.

17. The device of claim 14, wherein the programmable circuit is configurable to send a second wired signal via a serial peripheral interface to the battery monitor circuit in response to receiving the packet.

18. A device comprising:
a wireless transmitter configurable to transmit a downlink packet;
a programmable circuit; and
a communication circuit coupled to the wireless transmitter and the programmable circuit, wherein the communication circuit is configurable to:
after transmission of the downlink packet, set a timer in response to a message from the programmable circuit; and
cause the device to send a wired signal to a battery monitor circuit at an expiration of the timer.

19. The device of claim 18, wherein the communication circuit is configurable to cause the device to send the wired signal to prompt the battery monitor circuit to perform a measurement of a battery upon receipt of the wired signal by the battery monitor circuit.

20. The device of claim 18, wherein the communication circuit is configurable to set the timer and cause the device to send the wired signal independently of software executed by the programmable circuit.
